(19) United States
(12) Patent Application Publication
(10) Pub. No.: US 2011/0198602 A1
(43) Pub. Date: Aug. 18, 2011

(54) ALUMINUM ALLOY FILM FOR DISPLAY DEVICE, DISPLAY DEVICE, AND SPUTTERING TARGET

(75) Inventors: Akira Nanbu, Hyogo (JP); Hiroshi Goto, Hyogo (JP); Aya Miki, Hyogo (JP); Hiroyuki Okuno, Hyogo (JP); Junichi Nakai, Hyogo (JP); Tomoya Kishi, Hyogo (JP); Toshiaki Takagi, Hyogo (JP); Shigenobu Namba, Hyogo (JP); Mamoru Nagao, Hyogo (JP); Nobuhiro Kobayashi, Hyogo (JP)

(73) Assignee: Kabushiki Kaisha Kobe Seiko Sho (Kobe Steel, Ltd.), HYOGO (JP)

(21) Appl. No.: 13/122,937

(22) PCT Filed: Nov. 5, 2009
(86) PCT No.: PCT/JP2009/068923

§ 371 Date: Apr. 6, 2011

(30) Foreign Application Priority Data
Nov. 5, 2008 (JP) 2008-284893
Nov. 5, 2008 (JP) 2008-284894
Jan. 13, 2009 (JP) 2009-004687

(51) Int. Cl. H01L 33/08; C22C 21/00; C23C 14/34; C22C 21/12; H01L 33/16

(52) U.S. Cl. 257/59; 428/546; 204/298.13; 420/550; 420/538; 257/72; 257/E33.053

(57) ABSTRACT

Disclosed is an Al alloy film which can be in direct contact with a transparent pixel electrode in a wiring structure of a thin film transistor substrate that is used in a display device, and which has improved corrosion resistance against an amine remover liquid that is used during the production process of the thin film transistor. Also disclosed is a display device using the Al alloy film. Specifically disclosed is an Al alloy film for a display device, said Al alloy film being directly connected with a transparent conductive film on a substrate of a display device, and containing 0.05-2.0 atom % of Ge, at least one element selected from among element group X (Ni, Ag, Co, Zn and Cu), and 0.02-2 atom % of at least one element selected from among element group Q consisting of the rare earth elements. A Ge-containing deposit and/or a Ge-concentrated part is present in the Al alloy film for a display device. Also specifically disclosed is a display device comprising the Al alloy film.

### TECHNICAL FIELD

The present invention relates to an Al alloy film for a display device; a display device; and a sputtering target.

### BACKGROUND ART

Liquid crystal display devices are used in various fields ranging from compact cellular phones to large-screen television sets of a size exceeding 30 inches. They include a TFT array substrate, a counter substrate, and a liquid crystal layer. The TFT array substrate uses thin-film transistors (hereinafter also referred to as “TFTs”) as switching elements and includes transparent pixel electrodes (display electrodes); interconnections such as gate interconnections and source-drain interconnections; and a semiconductor layer typically of amorphous silicon (a-Si) or polycrystalline silicon (p-Si). The counter substrate faces the TFT array substrate at a predetermined distance and includes a common electrode. The liquid crystal layer is a layer of a liquid crystal charged between the TFT array substrate and the counter substrate.

Pure aluminum (Al), or Al alloys such as Al—Nd alloys (hereinafter these are generically referred to as Al-based alloys) are generally used in the TFT array substrate as materials for the interconnections such as gate interconnections and source-drain interconnections, because the Al-based alloys have low electrical resistance and are easy to undergo microprocessing. Customary TFT array substrates generally further include a barrier metal layer between the Al-based alloy interconnection and the transparent pixel electrode, which barrier metal layer is made of a high-melting-point metal such as Mo, Cr, Ti, or W. The Al-based alloy interconnection is connected to the transparent pixel electrode through the barrier metal layer because of ensuring heat resistance and ensuring electroconductivity. Specifically, when the Al-based alloy interconnection is directly connected to the transparent pixel electrode, the contact resistance between them is high, and such a high contact resistance impairs the display quality of the screen and should be avoided. This is because Al constituting the interconnection to be directly connected to the transparent pixel electrode is very readily oxidized and forms an aluminum oxide insulating layer at the interface between the Al-based alloy interconnection and the transparent pixel electrode, which aluminum oxide is formed with oxygen generated in a film deposition process of the liquid crystal display and/or with oxygen added during the film deposition. A transparent conductive film typically of indium tin oxide (ITO) constituting the transparent pixel electrode is a conductive metal oxide, but the aluminum oxide layer thus formed impedes an electrical ohmic contact of the transparent conductive film.

To form an interconnection having a multilayer structure including a barrier metal layer, however, vacuum deposition of the interconnection should be performed in multiple steps typically using sputtering equipment of a cluster tool system. This requires an extra deposition chamber for the deposition of the barrier metal, in addition to film-deposition sputtering equipment for the deposition typically of the gate electrode, source electrode, and drain electrode. The increase in fabrication cost and decrease in productivity due to the formation of the barrier metal layer become not trivial, as cost reduction becomes more and more necessary in large-scale fabrication of the liquid crystal display. In addition, the multilayer structure of different metals impedes the formation of a good tapered shape in the patterning of the interconnection, because of differences in etching rate and potential between the different metals.

The interconnection material undergoes a thermal hysteresis during the fabrication process of the liquid crystal display device and should thereby have heat resistance. The TFT array substrate has a multilayer structure of thin films and receives heat of around 300° C. through chemical vapor deposition (CVD) and a heat treatment after the formation of the interconnection. Typically, aluminum has a melting point of 660° C., but the (Al-based) interconnection material should be resistant to plastic deformation at 300° C. This is because there is a difference in heat expansion coefficient between the metal constituting the interconnection material and the glass substrate, and, once the interconnection material and the glass substrate undergo a thermal hysteresis, the difference in heat expansion coefficient causes stress between the metal thin film (interconnection material) and the glass substrate, and the stress acts as a driving force and causes diffusion of the metal element to thereby cause plastic deformations such as hillocks and voids, which impair the yield.

Under these circumstances, there have been proposed electrode materials and fabrication methods thereof, which eliminate the need of the formation of a barrier metal layer and allow an Al-based alloy interconnection to be directly connected to a transparent pixel electrode.

Typically, the applicants of the present invention have disclosed direct contact techniques which eliminate the need of the barrier metal layer, which can be performed in a simple manner without increasing the number of steps, and which allow the Al-based alloy interconnection to be directly and reliably connected to the transparent pixel electrode (Patent Literature (PTL) 1 to 4). Specifically, these literatures describe that, according to the techniques, electroconductivity at the interface between a transparent conductive film typically of ITO or IZO (indium zinc oxide) and an aluminum alloy film is ensured by the action of precipitates derived from an alloy element dispersed in the Al alloy film. More specifically, PTL 1 discloses an Al alloy which shows a sufficiently low electrical resistance even when subjected to a heat treatment at a low temperature and which also shows satisfactory heat resistance. Specifically, PTL 1 discloses an Al alloy film composed of an Al-a-X alloy containing at least one element selected from the group consisting of Ni, Ag, Zn, Cu, and Ge (hereinafter also referred to as “α component”) and at least one element selected from the group consisting of Mg, Cr, Mn, Ru, Rh, Pd, Ir, Pt, La, Ce, Pr, Gd, Tb, Sm, Eu, Ho, Er, Tm, Yb, Lu, and Dy (hereinafter also referred to as “X component”). The literature describes that the use of the Al alloy film in a thin-film transistor substrate (TFT array substrate) eliminates the need of a barrier metal layer and allows the Al alloy film to be in direct and reliable contact with a transparent pixel electrode made of a conductive oxide film, without increasing the number of steps. The literature also describes that the Al alloy film can have a low electrical resistance and excellent heat resistance even when the Al alloy film is subjected to a heat treatment at a low temperature typically of about 100° C. or higher and 300° C. or lower. PTL 3 describes that an Al—Ni alloy containing a specific amount of boron (B), when used as an interconnection material for a display device structurally including the interconnection directly connected to a transparent electrode layer or semiconductor layer, avoids contact failure or avoids increase in contact resistance due to the direct contact.

PTL 5 describes that an aluminum alloy thin film containing carbon and further containing at least one element selected from the group consisting of nickel, cobalt, and iron in a content of 0.5 to 7.0 atomic percent can be an aluminum alloy thin film which has an electrode potential equivalent to that of the ITO film, which has a low resistivity without the diffusion of silicon, and which has excellent heat resistance.

PTL 6 discloses an Al alloy containing, as an alloy component, at least one element selected from the group consisting of Au, Ag, Zn, Cu, Ni, Sr, Ge, Sm, and Bi in a content of 0.1 to 6 atomic percent. An Al-based alloy interconnection composed of the Al alloy can have a lower contact resistance with respect to the transparent pixel electrode even without the use of a barrier metal layer, because at least part of the alloy components is present as a precipitate or an enriched layer at the interface between the Al-based alloy interconnection and the transparent pixel electrode.

PTL 1 and PTL 6 propose direct contact techniques relating to an Al-based alloy interconnection which shows a low contact resistance even when directly connected to the transparent pixel electrode, which has a low electrical resistance of itself, and which preferably excels in heat resistance and corrosion resistance. PTL 1 and PTL 6 describe that the addition of elements such as Ni, Ag, Zn, and Co in a specific amount allows the Al-based alloy interconnection to have a low contact resistance with respect to the transparent pixel electrode and to have a low electrical resistance of itself. PTL 1 and PTL 6 also describe that the Al-based alloy interconnection shows improved heat resistance by adding one or more rare-earth elements such as La, Nd, Gd, and Dy. They further describe in various embodiments that corrosion resistance to an alkali developer and corrosion resistance to an alkali-cleaning after the development can be improved.

### CITATION LIST

### Patent Literature

PTL 1: Japanese Unexamined Patent Application Publication (JP-A) No. 2006-261636
PTL 2: Japanese Unexamined Patent Application Publication (JP-A) No. 2007-142356
PTL 3: Japanese Unexamined Patent Application Publication (JP-A) No. 2007-186779
PTL 4: Japanese Unexamined Patent Application Publication (JP-A) No. 2008-124499
PTL 5: Japanese Unexamined Patent Application Publication (JP-A) No. 2003-89864
PTL 6: Japanese Unexamined Patent Application Publication (JP-A) No. 2004-214606

### SUMMARY OF INVENTION

### Technical Problem

As is shown in PTL 1 to 4, the alloy elements, when added to pure Al, impart various functions to the resulting Al alloy, which functions are not found in the pure Al. For example, the Al alloy surely has satisfactory electroconducting properties (ITO direct-contact properties) between the transparent conductive film and the Al alloy film.

However, as is shown in PTL 1 to 4, the Al alloy film for use in the absence of a barrier metal layer should also have further excellent corrosion resistance. In particular, the TFT array substrate undergoes two or more wet processes during its fabrication process, and, in this case, the addition of a metal having a potential more noble than that of Al causes galvanic corrosion and thereby impairs the corrosion resistance. Typically, the TFT array substrate is subjected to continuous washing with water using an organic stripper containing an amine in a cleaning process for stripping or removing a photoresist (resin) film formed in a photolithography process. However, the amine forms a basic solution as a mixture with water, and this corrodes aluminum in a short time. In this connection, the Al alloy has undergone a thermal hysteresis by passing through a CVD process before passing through the stripping/cleaning process; and during the thermal hysteresis, alloy components form precipitates in the Al matrix. As there is a large difference in potential between the precipitates and aluminum, at the instance when the amine in the stripper comes in contact with water, the galvanic corrosion causes alkali corrosion to proceed, and aluminum, which is less electrochemically noble, is ionized and dissolves out to form pits as pitting corrosion (black dots, black dot-like etching marks). The black dot-like etching marks do not adversely affect the electroconducting properties at the interface between the ITO film and the Al alloy film but may be evaluated as defects in an inspection process in the fabrication process of the TFT array substrate, thus causing a lower yield.

The techniques disclosed in PTL 1 to 4 fail to make a sufficient study, while focusing on the pitting corrosion as pits, on the control of shape of the precipitates so as to suppress the generation of the pitting corrosion. As a result, they fail to recognize the significance of reliable improvement of the yield in the inspection process.

The present invention has been made under these circumstances, and an object of the present invention is to provide an Al alloy film for a display device, which shows high resistance to a stripper used in the fabrication process of the display device and also has excellent heat resistance, on the precondition that the Al alloy film reliably has a low contact resistance when it is directly connected to a transparent pixel electrode without the interposition of the barrier metal layer, in contrast to the known techniques.

Independently, alloy elements, when added to pure Al, impart various functions to the resulting Al alloy, which functions are not found in the pure Al, as described above. However, when the precipitates, for example, are precipitated so as to allow the Al alloy film to be directly connected to the transparent pixel electrode, the precipitates may become significantly coarse, and the coarse precipitates may cause black dots. For this reason, there has been made a demand to provide a technique which sufficiently and reliably allows the Al alloy film to have a low contact resistance, instead of the precipitation of the coarse precipitates. The present invention has been made also focusing these circumstances, and another object of the present invention is to provide an Al alloy film for a display device which sufficiently and reliably shows a low contact resistance even when directly connected to a transparent pixel electrode without the interposition of a barrier metal layer.

Yet another object of the present invention is to provide an Al alloy film for a display device, and to provide a display device using the same, which Al alloy film shows a low contact resistance when directly connected to the transparent pixel electrode without the interposition of a barrier metal layer, which also has a low electrical resistance of itself, and which preferably excels also in heat resistance and corrosion resistance.

### Solution to Problem

The present invention will be summarized below.

[1] An Al alloy film for a display device, to be arranged on or above a substrate of the display device and to be directly connected to a transparent conductive film,

the Al alloy film containing:

germanium (Ge) in a content of 0.05 to 2.0 atomic percent;

at least one element selected from the Element Group X consisting of Ni, Ag, Co, Zn, and Cu; and

at least one element selected from the Element Group Q consisting of rare-earth elements in a content of 0.02 to 2 atomic percent,

in which the Al alloy film includes at least one of a Ge-containing precipitate and a Ge-enriched area.

[2] The Al alloy film for a display device, according to [1],

in which the Al alloy film contains:

Ge in a content of 0.05 to 1.0 atomic percent;

at least one element selected from, of the Element Group X, the group consisting of Ni, Ag, Co, and Zn in a content of 0.03 to 2.0 atomic percent; and

at least one element selected from the Element Group Q consisting of rare-earth elements in a content of 0.05 to 0.5 atomic percent, and

in which the Al alloy film includes Ge-containing precipitates having a major axis of 20 nm or more in a number density of 50 or more per 100 μm².

[3] The Al alloy film for a display device, according to [2], in which the rare-earth elements are selected from the group consisting of Nd, Gd, La, Y, Ce, Pr, and Dy.
[4] The Al alloy film for a display device, according to [2] or [3], further containing, of the Element Group X, Cu in a content of 0.1 to 0.5 atomic percent.
[5] The Al alloy film for a display device, according to any one of [2] to [4], in which the Al alloy film has a ratio [(Group X element)/(Group Q element)] of more than 0.1 and 7 or less, where the ratio is the ratio of the content (atomic percent) of the at least one element selected from the Element Group X (Group X element) to the content (atomic percent) of the at least one element selected from the Element Group Q (Group Q element).
[6] The Al alloy film for a display device, according to any one of [2] to [5], in which the Al alloy film contains Ge in a content of 0.3 to 0.7 atomic percent.
[7] The Al alloy film for a display device, according to any one of [1] to [6], in which the Ge-containing precipitates in the Al alloy film are directly connected to the transparent conductive film.
[8] The Al alloy film for a display device, according to [1],

in which the Al alloy film contains:

Ge in a content of 0.2 to 2.0 atomic percent;

at least one element selected from, of the Element Group X, the group consisting of Ni, Co, and Cu; and

at least one element selected from the Element Group Q consisting of rare-earth elements in a content of 0.02 to 1 atomic percent, and

in which the Al alloy film has a number density of precipitates having a grain size of more than 100 nm of 1 or less per 10⁻⁶ cm².

[9] The Al alloy film for a display device, according to [8], in which the Al alloy film contains at least one element selected from the Element Group X in a content of 0.02 to 0.5 atomic percent.
[10] The Al alloy film for a display device, according to [8] or [9], in which the content of the at least one element selected from the Element Group X satisfies following Expression (1):

10(Ni+Co+Cu)≦5 (1)

wherein “Ni”, “Co”, and “Cu” in Expression (1) represent the contents (in units of atomic percent) of the respective elements in the Al alloy film.
[11] The Al alloy film for a display device, according to [1], in which the Al alloy film comprises:

Ge in a content of 0.1 to 2 atomic percent; and

at least one element selected from, of the Element Group X, the group consisting of Ni and Co in a content of 0.1 to 2 atomic percent, and

the Al alloy film includes at least one Ge-enriched area being present at an aluminum matrix grain boundary and having a Ge concentration (atomic percent) of more than 1.8 times the Ge concentration (atomic percent) of the entire Al alloy film.

[12] The Al alloy film for a display device, according to [11], in which the Al alloy film has a ratio [Ge/(Ni+Co)] of the Ge content to the total content of Ni and Co of 1.2 or more.
[13] The Al alloy film for a display device, according to [11] or [12], further containing, of the Element Group X, Cu in a content of 0.1 to 6 atomic percent.
[14] The Al alloy film for a display device, according to [13], in which the Al alloy film has a ratio [Cu/(Ni+Co)] of the Cu content to the total content of Ni and Co of 0.5 or less.
[15] A display device containing at least one thin-film transistor including the Al alloy film for a display device, according to any one of [1] to [14].
[16] A sputtering target for depositing an Al alloy film, the Al alloy film to be arranged on or above a substrate of a display device and to be directly connected to a transparent conductive film,

the sputtering target containing:

Ge in a content of 0.05 to 2.0 atomic percent;

at least one element selected from the Element Group X consisting of Ag, Ni, Co, Zn, and Cu; and

at least one element selected from the Element Group Q consisting of rare-earth elements in a content of 0.02 to 2 atomic percent,

with the remainder including Al and inevitable impurities.

[17] The sputtering target according to [16], comprising:

Ge in a content of 0.05 to 1.0 atomic percent;

at least one element selected from, of the Element Group X, the group consisting of Ni, Ag, Co, and Zn in a content of 0.03 to 2.0 atomic percent; and

at least one element selected from the Element Group Q consisting of rare-earth elements in a content of 0.05 to 0.5 atomic percent.

[18] The sputtering target according to [17], further containing, of the Element Group X, Cu in a content of 0.1 to 0.5 atomic percent.
[19] The sputtering target according to [16], in which the sputtering target has a ratio [(Group X element)/(Group Q element)] of more than 0.1 and 7 or less, where the ratio is the ratio of the content (atomic percent) of the at least one element selected from the Element Group X (Group X element) to the content (atomic percent) of the at least one element selected from the Element Group Q (Group Q element).

### Advantageous Effects of Invention

An Al alloy film according to an embodiment of the present invention can be directly connected to a transparent pixel electrode (transparent conductive film, oxide conductive film) without the interposition of a barrier metal layer and sufficiently and reliably has a low contact resistance. An Al alloy film for a display device according to another embodiment excels also in corrosion resistance (stripper resistance). In addition, an Al alloy film for a display device according to yet another embodiment also excels in heat resistance. The Al alloy films according to the present invention, when adopted to a display device, eliminate the need of the barrier metal layer. Accordingly, the Al alloy films according to the present invention can give a display device which has excellent productivity, which is available at low cost, and which has high performance.

### BRIEF DESCRIPTION OF DRAWINGS

FIG. 1 is a schematic enlarged cross sectional view showing the structure of a representative liquid crystal display to which an amorphous silicon TFT array substrate is adopted.

FIG. 2 is a schematic cross sectional view showing the structure of a TFT array substrate according to a first embodiment of the present invention.

FIG. 3 is a schematic diagram sequentially illustrating an exemplary fabrication process for the TFT array substrate in FIG. 2.

FIG. 4 is a schematic diagram sequentially illustrating the exemplary fabrication process for the TFT array substrate in FIG. 2.

FIG. 5 is a schematic diagram sequentially illustrating the exemplary fabrication process for the TFT array substrate in FIG. 2.

FIG. 6 is a schematic diagram sequentially illustrating the exemplary fabrication process for the TFT array substrate in FIG. 2.

FIG. 7 is a schematic diagram sequentially illustrating the exemplary fabrication process for the TFT array substrate in FIG. 2.

FIG. 8 is a schematic diagram sequentially illustrating the exemplary fabrication process for the TFT array substrate shown in FIG. 2.

FIG. 9 is a schematic diagram sequentially illustrating the exemplary fabrication process for the TFT array substrate in FIG. 2.

FIG. 10 is a schematic diagram sequentially illustrating the exemplary fabrication process for the TFT array substrate in FIG. 2.

FIG. 11 is a schematic cross sectional view showing the structure of a TFT array substrate according to a second embodiment of the present invention.

FIG. 12 is a schematic diagram sequentially illustrating an exemplary fabrication process for the TFT array substrate in FIG. 11.

FIG. 13 is a schematic diagram sequentially illustrating the exemplary fabrication process for the TFT array substrate in FIG. 11.

FIG. 14 is a schematic diagram sequentially illustrating the exemplary fabrication process for the TFT array substrate in FIG. 11.

FIG. 15 is a schematic diagram sequentially illustrating the exemplary fabrication process for the TFT array substrate in FIG. 11.

FIG. 16 is a schematic diagram sequentially illustrating the exemplary fabrication process for the TFT array substrate in FIG. 11.

FIG. 17 is a schematic diagram sequentially illustrating the exemplary fabrication process for the TFT array substrate shown in FIG. 11.

FIG. 18 is a schematic diagram sequentially illustrating the exemplary fabrication process for the TFT array substrate in FIG. 11.

FIG. 19 is a photograph of an Al-(0.2 atomic percent Ni)-(0.35 atomic percent La) alloy film in the observation under a scanning electron microscope (SEM) in Experimental Example 1.

FIG. 20 is a photograph of an Al-(0.5 atomic percent Ge)-(0.02 atomic percent Sn)-(0.2 atomic percent La) alloy film in the observation under a SEM in Experimental Example 1.

FIG. 21 is a photograph of an Al-0.5 atomic percent Ge-0.1 atomic percent Ni-0.2 atomic percent La alloy film in the observation under a SEM in Experimental Example 1.

FIG. 22 is a photograph of an Al-0.2 atomic percent Ni-0.35 atomic percent La alloy film in the observation under an optical microscope in Experimental Example 1.

FIG. 23 is a photograph of an Al-(0.5 atomic percent Ge)-(0.02 atomic percent Sn)-(0.2 atomic percent La) alloy film in the observation under an optical microscope in Experimental Example 1.

FIG. 24 is a photograph of an Al-(0.5 atomic percent Ge)-(0.1 atomic percent Ni)-(0.2 atomic percent La) alloy film in the observation under an optical microscope in Experimental Example 1.

FIG. 25 is a diagram showing an electrode pattern formed in Experimental Example 2.

FIG. 26 is a photograph of Sample No. 5 in the observation under a transmission electron microscope (TEM) in Experimental Example 2.

FIG. 27 is a photograph of Sample No. 14 in the observation under a TEM in Experimental Example 2.

FIG. 28 is a graph showing a Ge concentration profile of Sample No. 3 in Table 4.

FIG. 29 is a photograph of the vicinity of a measuring point of the Ge concentration at the aluminum matrix grain boundary in the observation under a TEM in Experimental Example 3.

FIG. 30 is a diagram showing a Kelvin pattern (TEG pattern) used for the measurement of the direct contact resistance between Al alloy films and a transparent pixel electrode in Experimental Example 3.

### DESCRIPTION OF EMBODIMENTS

The present invention will be illustrated in detail below.

It should be noted that the following description on constituents is made as one example (representative example) of embodiments of the present invention and is never intended to limit the scope of the present invention.

The present invention relates to, in an embodiment, an Al alloy film for a display device which is to be arranged on or above a substrate of the display device and to be directly connected to a transparent conductive film, in which the Al alloy film contains Ge in a content of 0.05 to 2.0 atomic percent; at least one element selected from the Element Group X consisting of Ni, Ag, Co, Zn, and Cu; and at least one element selected from the Element Group Q consisting of rare-earth elements in a content of 0.02 to 2 atomic percent, and the Al alloy film includes a Ge-containing precipitate and/or a Ge-enriched area.

As used herein the term “Ge-enriched area” refers to an area corresponding to an aluminum matrix grain boundary and having a Ge concentration higher than the Ge concentration of the entire Al alloy film in a predetermined ratio or more.

Of the Al alloy films for a display device according to the present invention, a preferred first embodiment is an Al alloy film for a display device in which the Al alloy film contains Ge in a content of 0.05 to 1.0 atomic percent; at least one element selected from, of the Element Group X, the group consisting of Ni, Ag, Co, and Zn in a content of 0.03 to 2.0 atomic percent; and at least one element selected from the Element Group Q consisting of rare-earth elements in a content of 0.05 to 0.5 atomic percent, and the Al alloy film includes Ge-containing precipitates having a major axis of 20 nm or more in a number density of 50 or more per 100 μm².

A preferred second embodiment is an Al alloy film for a display device, in which the Al alloy film contains Ge in a content of 0.2 to 2.0 atomic percent; at least one element selected from, of the Element Group X, the group consisting of Ni, Co, and Cu; and at least one element selected from the Element Group Q consisting of rare-earth elements in a content of 0.02 to 1 atomic percent, and the Al alloy film has a number density of precipitates having a grain size of more than 100 nm of 1 or less per 10⁻⁶ cm².

A preferred third embodiment is an Al alloy film, in which the Al alloy film contains Ge in a content of 0.1 to 2 atomic percent; and at least one element selected from, of the Element Group X, the group consisting of Ni and Co in a content of 0.1 to 2 atomic percent, and the Al alloy film includes at least one Ge-enriched area being present at an aluminum matrix grain boundary and having a Ge concentration (atomic percent) of more than 1.8 times the Ge concentration (atomic percent) of the entire Al alloy film.

Initially, the preferred first embodiment will be illustrated in detail below.

The present inventors made investigations about how the contact resistance is affected by alloy elements added to Al and by dimensions of precipitates containing the alloy elements, in order to provide an Al alloy film for a display device which sufficiently and reliably shows a low contact resistance when directly connected to the transparent pixel electrode without the interposition of a barrier metal layer. It has been believed that when precipitates containing the alloy elements added to Al are precipitated at the contact interface with respect to the transparent pixel electrode, the precipitates allow electricity to pass therethrough more easily and thereby provides a low contact resistance, as described in PTL 6. However, some of precipitates, such as Al—Ni precipitates, may become significantly coarse, be corroded by a stripper used in the fabrication process, and thereby cause black dots. In contrast, excessively small precipitates may not sufficiently contribute to the reduction in contact resistance and may be provably removed during contact etching and cleaning processes.

From these viewpoints, the present inventors made investigations on precipitates which are in a preferred form and which can be adopted instead of the Al—Ni and other precipitates. As a result, they have found that Ge-containing precipitates do not become significantly coarse, thereby hardly cause the black dots, and effectively contribute to the low contact resistance; and that the presence of a large number of Ge-containing precipitates having a major axis of 20 nm or more is preferred to achieve a low contact resistance reliably.

The Ge-containing precipitates, which are smaller than the Al—Ni and other precipitates, are effective to achieve the low contact resistance. While remaining unknown, this is probably because most of the contact current between the Al alloy film and the transparent pixel electrode (such as an ITO film) passes through the Ge-containing precipitates having a major axis of 20 nm or more, which are present in a large number at the interface between the Al alloy film and the transparent pixel electrode, and this lowers the contact resistance. These were demonstrated by the results in after-mentioned Experimental Examples. Exemplary Ge-containing precipitates in the Al alloy film having an after-mentioned chemical composition include Al-(at least one element selected from the group consisting of Ni, Ag, Co, and Zn)—Ge precipitates; Al—Ge-(at least one rare-earth element (Group Q element)) precipitates; (at least one element selected from the group consisting of Ni, Ag, Co, and Zn)—Ge-(at least one Group Q element) precipitates; and Ge-(at least one Group Q element) precipitates.

The major axes of the Ge-containing precipitates are not critical in upper limit, as long as being 20 nm or more. However, the maximum of the major axes of the Ge-containing precipitates may be about 150 nm from the viewpoint of operation. For achieving a sufficiently low contact (resistance), the Ge-containing precipitates having a major axis of 20 nm or more are present in a number density of preferably 50 or more per 100 μm², more preferably 100 or more per 100 μm², and furthermore preferably 500 or more per 100 μm².

The major axis and number density are measured herein according to methods described in the after-mentioned Experimental Examples.

The present invention further made investigations on the chemical composition of the Al alloy film so as to easily precipitate the Ge-containing precipitates in the specific form and to allow the Al alloy film to excel also in heat resistance. Reasons why the chemical composition is specified in the preferred first embodiment will be described in detail below.

As described above, the Al alloy film according to the present invention contains Ge-containing precipitates and preferably contains, as an alloy element therein, Ge in a content of 0.05 to 1.0 atomic percent (at %). Germanium (Ge) should be contained in a content of 0.05 atomic percent or more to allow the Ge-containing precipitates to be present at a certain level or more. The Ge content is preferably 0.1 atomic percent or more, and more preferably 0.3 atomic percent or more. In contrast, Ge, if present in an excessively high content, may increase the electrical resistance of the Al alloy film as an interconnection, and the upper limit of the Ge content is preferably 1.0 atomic percent. The Ge content is more preferably 0.7 atomic percent or less, and furthermore preferably 0.5 atomic percent or less.

The Al alloy film according to the present invention preferably contains, in combination with Ge, at least one element (Group X element) selected from the group consisting of Ni, Ag, Co, and Zn in a content of 0.03 to 2.0 atomic percent. The presence of Group X element and Ge both in specific contents allows easy precipitation of Ge-containing precipitates of relatively large sizes (major axes) of 20 nm or more and thereby provides a further low contact resistance.

To allow the Group X element to exhibit these operations and effects sufficiently, the content of Group X element is preferably 0.03 atomic percent or more, more preferably 0.05 atomic percent or more, and furthermore preferably 0.1 atomic percent or more. However, the Group X element, if present in an excessively high content, may increase the electrical resistance of the Al alloy film itself and may cause precipitation of a large amount of Al-(Group X element) precipitates (such as Al₃Ni) to impair the corrosion resistance of the Al alloy film. Specifically, the Al-(Group X element) precipitates have a potential significantly different from that of the Al matrix and cause galvanic corrosion at the instance when the amine as a component of the organic stripper comes in contact with water typically in the cleaning process for removing the photoresist (resin). Upon the galvanic corrosion, aluminum which is electrochemically less noble is ionized to dissolve out to form pitting corrosion as pits (black dots). This causes the transparent conductive film (ITO film) to be discontinuous, which may be recognized as a defect in an appearance inspection, resulting in an insufficient yield. From these viewpoints, the upper limit of the content of the Group X element herein is preferably 2.0 atomic percent. The content of the Group X element is more preferably 0.6 atomic percent or less, and furthermore preferably 0.3 atomic percent or less.

The Al alloy film according to the present invention contains at least one element (Group Q element) selected from the Element Group Q consisting of rare-earth elements (of which Nd, Gd, La, Y, Ce, Pr, and Dy are preferred; and Nd and La are more preferred).

The substrate on which the Al alloy film has been deposited is subjected to the formation of a silicon nitride film (protective film) typically through chemical vapor deposition (CVD). In this process, applied heat at high temperatures causes thermal expansion of the Al alloy film and the substrate, but the two members are different in coefficient of thermal expansion, and the difference probably causes hillocks (nodular protrusions). However, the presence of the rare-earth element suppresses the generation of the hillocks. In addition, the presence of the rare-earth element (Group Q element) also improves, as corrosion resistance, the resistance to the stripper used for removing the photosensitive (photoresist) resin.

To ensure the heat resistance and to increase the corrosion resistance, the Al alloy film contains at least one element (Group Q element) selected from the group consisting of rare-earth elements (of which Nd, Gd, La, Y, Ce, Pr, and Dy are preferred) in a content of preferably 0.05 atomic percent or more, and more preferably 0.2 atomic percent or more. However, the rare-earth element (Group Q element), if present in an excessively high content, may increase the electrical resistance of the Al alloy film itself after the heat treatment. Accordingly, the total content of the rare-earth elements (Group Q elements) is preferably 0.5 atomic percent or less, and more preferably 0.3 atomic percent or less.

As used herein the term “rare-earth elements” refers to the group of elements including lanthanoid elements as well as Sc (scandium) and Y (yttrium), in which the lanthanoid elements include a total of 15 elements ranging from La (atomic number 57) to Lu (atomic number 71) in the periodic table of elements.

The Al alloy film contains the Group X element, Ge, and the Group Q element, with the remainder including Al and inevitable impurities. Exemplary precipitates formed in the Al-(Group X element)-Ge-(Group Q element) alloy include those as mentioned above, such as Al-(Group X element)-Ge and (Group X element)-Ge-(Group Q element) precipitates. For suppressing the precipitation of Al-(Group X element) precipitates which impair the corrosion resistance of the Al alloy film, it is effective to allow Ge-containing precipitates containing the Group X element to precipitate in a large amount to thereby consume the Group X element which is necessary for the formation of the Al-(Group X element) precipitates. Specifically, it is effective to control the content of the Group X element and the amount of the Ge-containing precipitates in the Al alloy film.

When the Ge content in the Al alloy film is constant, the amount of the Ge-containing precipitates depends on the content of the Group Q element in the Al alloy film. Accordingly, the Al alloy film preferably has a ratio [(Group X element)/(Group Q element)] of more than 0.1 and 7 or less, for suppressing the formation of the Al-(Group X element) precipitates, in which the ratio is the ratio of the content (atomic percent) of the Group X element to the content (atomic percent) of the Group Q element. The ratio [(Group X element)/(Group Q element)] is more preferably 0.2 or more and is more preferably 4 or less and further more preferably 1 or less.

The Al alloy film contains at least one element selected from the group consisting of Ni, Ag, Co, and Zn; Ge; and at least one element selected from the group consisting of rare-earth elements (Group Q element) in the specific contents, with the remainder including Al and inevitable impurities. It is effective to further add Cu to the Al alloy film so as to precipitate the Ge-containing precipitates in a further larger number.

Copper (Cu) element precipitates as fine nuclei for Ge-containing precipitates and is effective for the precipitation of the Ge-containing precipitates in a further lager amount. To allow Cu to exhibit these advantageous effects sufficiently, Cu is preferably contained in a content of 0.1 atomic percent or more, and more preferably 0.3 atomic percent or more. However, Cu, if present in an excessively high content, may impair the corrosion resistance. For this reason, the Cu content is preferably 0.5 atomic percent or less.

Next, the preferred second embodiment will be described in detail below.

The present inventors made intensive investigations to provide an Al alloy film which has excellent resistance (corrosion resistance) to an agent (stripper) used in the fabrication process of the display device and suffers from, if any, black dots (black dot-like etching marks) in such a less amount as not to be evaluated as defective in an inspection process in the fabrication process for the TFT array substrate. The investigations were made on the precondition that the Al alloy film has a sufficiently low contact resistance even when it is directly connected to the transparent pixel electrode without the interposition of a barrier metal layer.

As a result, the present inventors have found that it is effective to add specific amounts of Ge and at least one element (Group X element) selected from, of the Element Group X, the group consisting of Ni, Co, and Cu for achieving a low contact resistance when the Al alloy film is directly connected to the transparent pixel electrode without the interposition of a barrier metal layer; and that black dots generated around precipitates can be controlled to be fine and to have an invisible size by appropriately controlling the contents of the alloy elements and/or adding two or more alloy elements in a suitable combination, and by controlling the film deposition conditions.

Specifically, the present inventors have found that the Al alloy film preferably has a number density of precipitates having a grain size of more than 100 nm of 1 or less per 10⁻⁶ cm², and the resulting Al alloy film having this configuration is not evaluated as defective in the inspection process in the fabrication process of TFT array substrate, in which the grain size of each of the precipitates is defined as and measured as [((major axis)+(minor axis))/2]. Of the precipitates, a largest precipitate has a grain size of preferably 100 nm or less, more preferably 90 nm or less, and furthermore preferably 80 nm or less.

The number density (number per 10⁻⁶ cm²) of the precipitates having a grain size of more than 100 nm is determined according to a method shown in after-mentioned Experimental Examples.

The chemical composition and recommended fabrication conditions for finely dividing precipitates as mentioned above on the precondition to achieve a low contact resistance will be described in detail below.

The Al alloy film according to the present invention preferably contains Ge in a content of 0.2 to 2.0 atomic percent and contains at least one element (as Group X element) selected from the group consisting of Ni, Co, and Cu, as described above. The presence of Ge in combination with the Group X element as alloy elements in the Al alloy film accelerates the formation of precipitates being finer than those in customary Al alloy films, thereby suppressing the black dots. In addition, the Ge-containing precipitates contribute to the reduction in contact resistance. This is probably because most of the contact current between the Al alloy film and the transparent pixel electrode (such as an ITO film) passes through the Ge-containing precipitates.

To exhibit the advantageous effects sufficiently, the Ge content in the Al alloy film is preferably 0.2 atomic percent or more, and more preferably 0.3 atomic percent or more. In contrast, Ge, if present in an excessively high content, may increase the electrical resistance of the Al alloy film itself and decreases the corrosion resistance contrarily. For these reasons, the Ge content is preferably 2.0 atomic percent or less, more preferably 1.0 atomic percent or less, and furthermore preferably 0.4 atomic percent or less.

For the Group X elements, the content necessary for exhibiting the advantageous effects varies from element to element, and preferred contents of these elements are as follows. Specifically, of the Element Group X, when at least one element selected from the group consisting of Ni, Co, and Cu is to be contained, the content of the at least one element is preferably 0.02 to 0.5 atomic percent. The Al alloy film, if containing these elements in an excessively low content, may not easily have a sufficiently low contact resistance. For this reason, the at least one element selected from the group consisting of Ni, Co, and Cu is contained in a content of preferably 0.02 atomic percent or more, and more preferably 0.03 atomic percent or more. In contrast, the Al alloy film, if containing Ni, Co, and/or Cu in an excessively high content, may have a higher electrical resistance, and to avoid this, the total content of Ni, Co, and Cu is controlled to be preferably 0.5 atomic percent or less, and more preferably 0.35 atomic percent or less.

When Ni alone is contained as the Group X element, the Ni content is more preferably 0.2 atomic percent or less, and furthermore preferably 0.15 atomic percent or less. When Co alone is contained as the Group X element, the Co content is more preferably 0.2 atomic percent or less, and furthermore preferably 0.15 atomic percent or less.

The Al alloy film may further contain Ag. In this case, the Ag content is preferably 0.1 to 0.6 atomic percent. For achieving a sufficiently low contact resistance, the Ag content is preferably 0.1 atomic percent or more, and more preferably 0.2 atomic percent or more. In contrast, Ag, if present in an excessively high content, may often increase the electrical resistance of the Al alloy film itself. For this reason, the Ag content is controlled to be preferably 0.6 atomic percent or less, more preferably 0.5 atomic percent or less, and furthermore preferably 0.3 atomic percent or less.

The Al alloy film may further contain indium (In) and/or tin (Sn). In this case, the content of In and/or Sn is preferably 0.02 to 0.5 atomic percent. For achieving a sufficiently low contact resistance, the content of In and/or Sn is preferably 0.02 atomic percent or more and more preferably 0.05 atomic percent or more. In contrast, In and/or Sn, if present in an excessively high content, may often increase the electrical resistance of the film itself and may cause insufficient adhesion between the Al alloy film and an underlayer. For this reason, the In and/or Sn content is controlled to be preferably 0.5 atomic percent or less.

When indium (In) alone is contained, the In content is more preferably 0.2 atomic percent or less, and furthermore preferably 0.15 atomic percent or less. When tin (Sn) alone is contained, the Sn content is more preferably 0.2 atomic percent or less, and furthermore preferably 0.15 atomic percent or less.

When Ni is added in combination with Ag or when Co is added in combination with Ag, both elements in combination undergo phase separation with each other, and the respective elements respectively independently diffuse and form precipitates. The contents of the respective added elements are desirably controlled to be within such a range (equal to the range when the element in question alone is added) as not to cause coarse precipitates. Specifically, the Ni content is preferably 0.2 atomic percent or less, and more preferably 0.15 atomic percent or less. The Ag content is preferably 0.5 atomic percent or less, and more preferably 0.3 atomic percent or less. The Co content is preferably 0.2 atomic percent or less, and more preferably 0.15 atomic percent or less.

Independently, when two or more Group X elements are used in such a combination as to form a complete solid solution or compound, the two or more elements are used within such contents as mentioned below, because the type and form of precipitates vary depending on the types of the Group X elements. Specifically, the contents of elements belonging to the Element Group X preferably satisfy following Expression (1). The left-hand side in following Expression (1) is more preferably 2 atomic percent or less, and furthermore preferably 1 atomic percent or less.

10(Ni+Co+Cu)≦5 (1)

In Expression (1), “Ni”, “Co”, and “Cu” represent the contents (in units of atomic percent) of the respective elements in the Al alloy film.

The Al alloy film, when containing at least one of Ag, In, and Sn, preferably satisfy following Expression (2). The left-hand side in following Expression (2) is more preferably 2 atomic percent or less, and furthermore preferably 1 atomic percent or less.

2Ag+10(In+Sn+Ni+Co+Cu)≦5 (2)

In Expression (2), “Ag”, “In”, “Sn”, “Ni”, “Co”, and “Cu” represent the contents (in units of atomic percent) of the respective elements in the Al alloy film.

The Al alloy film according to this embodiment contains, in addition to the Group X element, at least one element (Group Q element) selected from the Element Group Q consisting of rare-earth elements. The presence of the Group Q element allows the Al alloy film to have sufficiently high resistance to the resist stripper used in the fabrication process. The substrate on which the Al alloy film has been deposited is then subjected to the formation of a silicon nitride film (protective film) typically through CVD. In this process, the applied heat at high temperatures causes thermal expansion of the Al alloy film and the substrate, but these two members are different in coefficient of thermal expansion, and this difference probably causes hillocks (nodular protrusions). However, the presence of the rare-earth element suppresses the generation of the hillocks and improves the heat resistance.

To exhibit the advantageous effects sufficiently, the content of the Group Q element is preferably 0.02 atomic percent or more, and more preferably 0.03 atomic percent or more. However, the Group Q element, if present in an excessively high content, may often increase the electrical resistance of the Al alloy film itself, as with the Group X element. For this reason, the content of the Group Q element is preferably 1 atomic percent or less, and more preferably 0.7 atomic percent or less.

As used herein the term “rare-earth elements” refers to the group of elements including lanthanoid elements as well as Sc (scandium) and Y (yttrium), in which the lanthanoid elements include a total of 15 elements ranging from La (atomic number 57) to Lu (atomic number 71) in the periodic table of elements. Of the Group Q elements, La, Nd, Y, Gd, Ce, Dy, Ti, and Ta, for example, are more preferred, of which La and Nd are especially preferred. Each of these elements can be used alone or in an arbitrary combination.

Next, the preferred third embodiment will be described in detail below.

The present inventors made intensive investigations to provide an Al alloy film which has both a sufficiently low electrical resistance of itself and a sufficiently low contact resistance when the film is directly connected to the transparent pixel electrode without the interposition of a barrier metal layer. As a result, the present inventors have found that the use of a specific Al−(Ni/Co)−Ge alloy film achieves the object, which alloy film contains both Ge and at least one of Ni and Co and includes a Ge-enriched area corresponding to an aluminum matrix grain boundary and having a Ge concentration (atomic percent) at a specific level or more as compared to the Ge concentration (atomic percent) of the entire Al alloy film. They have also found that the addition of one or more rare-earth elements to the Al alloy film is effective for improving the heat resistance; and that the addition of Cu is effective for further stably reducing the contact resistance.

The Al alloy film according to the present invention has a major feature in including a Ge-enriched area. Specifically, the Al alloy film has a major feature in including a Ge-enriched area having a high Ge-segregation ratio of more than 1.8, in which the Ge-segregation ratio is the ratio of the Ge concentration at an aluminum matrix grain boundary to the Ge concentration in the Al alloy film. The Ge-enriched area is very effective for reducing and stabilizing the contact resistance. Specifically, the Ge-enriched area is very useful for stably ensuring a sufficiently low contact resistance without variation, regardless of the length of the cleaning time using a stripper. The Al alloy film according to the present invention, when used, can have a low contact resistance not only after a cleaning using a stripper performed for a time of about 1 to 5 minutes as in customary procedures, but also after a cleaning using a stripper performed for a remarkably time of about 10 to about 50 seconds significantly shorter than that in the customary procedures. The Al alloy film according to the present invention therefore advantageously eliminates the need of strict control of the cleaning time using a stripper and thereby increases the fabrication efficiency.

The Ge-enriched area, which significantly features the present invention, will be illustrated below, with reference to FIG. 28.

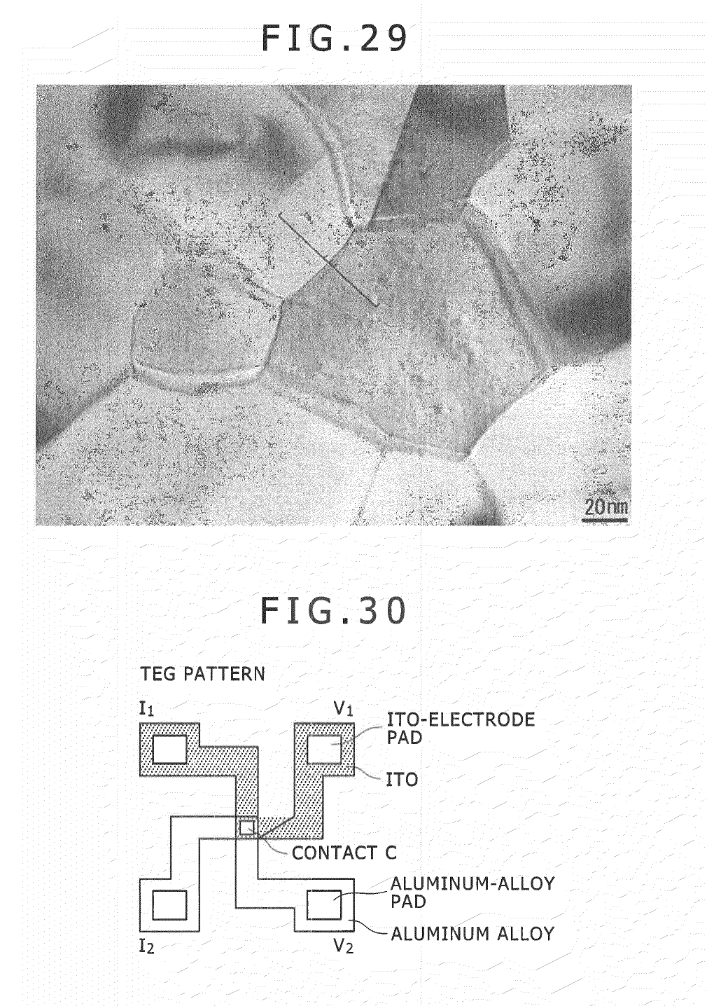

FIG. 28 is a graph showing a concentration profile of an Al grain boundary of Sample No. 3 (Al-(0.2 atomic percent Ni)-(0.5 atomic percent Ge)-(0.2 atomic percent La) alloy satisfying conditions specified in the present invention) in Table 4 of after-mentioned Experimental Example 3. FIG. 28 shows the result of analysis of the Ge content along a line substantially orthogonal to the grain boundary, as exemplified in FIG. 29 which shows the result of observation in after-mentioned Experimental Example 3. The graph in FIG. 28 is plotted with the abscissa indicating the distance (nm) from the grain boundary and the ordinate indicating the Ge concentration (atomic percent). The concentration profile in FIG. 28 demonstrates that the Al alloy film according to the present invention has a very high peak of Ge concentration of about 2.5 atomic percent at the grain boundary (in the vicinity of “0 nm” on the abscissa). The use of this Al alloy film controls the contact resistance with the ITO film as low as 1000Ω or less even when the cleaning using a stripper is performed for a time of shorter than 1 minute (e.g., 25 seconds or 50 seconds) (see Table 4). Certainly, it can control the contact resistance to be 1000Ω or less, even when the cleaning time using a stripper is set to be about 1 to 5 minutes as in customary procedures. Accordingly, the Al alloy film stably has a sufficiently low contact resistance regardless of the cleaning time using a stripper.

In contrast, a customary Al alloy film does not show the concentration profile as in FIG. 28 and does not substantially show enrichment of Ge to the grain boundary, in which the Al matrix and the grain boundary have substantially identical Ge concentrations. Typically, Sample No. 28 (customary example) in Table 4 has a Ge-segregation ratio of about 1.5, lower than those of examples, and does not include a Ge-enriched area (having a Ge-segregation ratio of more than 1.8) specified in the present invention, whereas the Ge concentration profile of Sample No. 28 is not shown. When the Al alloy film according to the customary example is used and the cleaning using a stripper is performed, the contact resistance between the Al alloy film and the ITO film significantly varies depending on the cleaning time, can be controlled to be 1000Ω or less (not shown in Table 4) at a cleaning time using a stripper of 1 minute or longer as in customary procedures, but becomes very high of more than 1000Ω as in Table 4 at a short cleaning time of 25 seconds. As is described above, the customary Al alloy film shows a large variation in contact resistance depending on the cleaning time using a stripper and should forcedly be strictly controlled on the cleaning process using a stripper.

The Ge-enriched area specified in the present invention can be obtained by further adding a predetermined heating treatment to any of a series of film deposition processes for sequentially depositing the Al alloy film, SiN film (insulating film), and ITO film. The heating treatment is performed at approximately 270° C. to 350° C. for about 5 to 30 minutes, and preferably at approximately 300° C. to 330° C. for 10 to 20 minutes. Germanium (Ge) and nickel (Ni) in Al have diffusion coefficients as follows. Germanium has a high diffusion coefficient (i.e., diffuses rapidly) and can thereby move to the grain boundary while suppressing the precipitates from becoming coarse, through a heat treatment for a short time as mentioned above.

Ge: 4.2×10⁻¹⁶ m²/s (300° C.)

Ni: 2.3×10⁻¹⁷ m²/s (300° C.)

The heating treatment may be performed typically after the deposition of the SiN film but before the deposition of the ITO film.

Next, the Al alloy film according to the third embodiment of the present invention will be illustrated in detail below.

The Al alloy film according to the present invention is preferably an Al−(Ni/Co)−Ge alloy film containing Ni and/or Co in a content of 0.1 to 2 atomic percent and Ge in a content of 0.1 to 2 atomic percent. Among these elements, Ni and/or Co element is very effective for reducing the contact resistance, and Ge element is enriched at the grain boundary and contributes to reduction and stabilization of the contact resistance.

Such an Al alloy film containing both Ge and at least one of Ni and Co has a lower and more stabilized contact resistance probably because fine precipitates are dispersed in a high number density and Ge is enriched at the aluminum matrix grain boundary according to the following mechanism.

Specifically, Ge has a lattice constant significantly different from that of Al (i.e., Ge has a large lattice mismatch), thereby more easily moves toward the grain boundary of the aluminum matrix as a result of the heat treatment, and the grain boundary at which Ge is present serves as a current path and stabilizes the contact property (contact resistance).

Copper (Cu) element, which is added as a selective component in the present invention, precipitates at low temperatures (precipitates in early stages of temperature rise from the viewpoint of temperature rise process) to increase the number of precipitation nuclei to thereby allow the precipitates to be fine. Probably for these reasons, this element contributes to the reduction and stabilization of the contact resistance.

Initially, the Al alloy film according to the present invention preferably contains Ni and/or Co in a content of 0.1 to 2 atomic percent. Ni and Co may be added alone or in combination. These elements are effective for reducing the contact resistance and for reducing the electrical resistance of the film itself and can exhibit such desired effects by controlling the content of either one or both of them within the above-specified range. The mechanism of the reduction in contact resistance is probably as follows. Precipitates containing conductive Ni and/or Co are formed at the interface between the Al alloy film and the transparent pixel electrode, and most of the contact current between the Al alloy film and the transparent pixel electrode (such as an ITO film) passes through the precipitates. In addition, the grain boundary, at which Ge is present, serves also as a current path to further reduce the contact resistance.

The Al alloy film preferably has a content of Ni and/or Co of 0.1 atomic percent or more, for the formation of the conductive precipitates in a large number to thereby further reduce the contact resistance. A preferred lower limit of the content of Ni and/or Co is 0.2 atomic percent. However, Ni and/or Co, if present in an excessively high content, may increase the electrical resistance of the film itself, and thereby the content of Ni and/or Co is preferably 2 atomic percent or less. A preferred upper limit of the content of Ni and/or Co is 1.5 atomic percent.

In addition, the Al alloy film according to the present invention preferably contains Ge in a content of 0.1 to 2 atomic percent. As is described above, the present invention allows Ge to be segregated highly at the grain boundary to reduce the contact resistance (especially to achieve a stable, low contact resistance which does not depend on the cleaning time). The segregation of Ge at the grain boundary is archived by controlling the Ge content to be 0.1 atomic percent or more. A preferred lower limit of the Ge content is 0.3 atomic percent. However, Ge, if present in an excessively high content, may increase the electrical resistance of the Al alloy film itself, and a preferred upper limit of the Ge content is 2 atomic percent. A more preferred upper limit of the Ge content is 1.2 atomic percent.

The ratio [Ge/(Ni+Co)] of the Ge content to the total content of Ni and Co is preferably 1.2 or more, for further reducing the contact resistance. This is probably because Ge is known to be readily present not only at the grain boundary as described above but also in precipitates containing Ni and/or Co, and the addition of Ge in a specific amount or more with respect to the amount of Ni and/or Co constituting the precipitates allows these elements to exhibit further higher effects of reducing the contact resistance. The [Ge/(Ni+Co)] ratio is more preferably more than 1.8. Although not critical from the viewpoint of reducing the contact resistance, the upper limit of the ratio is preferably about 5 in consideration typically of the stabilization of the contact resistance.

The Al alloy film according to the present invention contains the above-mentioned elements as basic component, with the remainder including Al and inevitable impurities.

The Al alloy film further contains at least one rare-earth element (Group Q element) for higher heat resistance. As used herein the term “rare-earth elements” refers to the group of elements including lanthanoid elements as well as Sc (scandium) and Y (yttrium), in which the lanthanoid elements include a total of 15 elements ranging from La (atomic number 57) to Lu (atomic number 71) in the periodic table of elements. The Al alloy film according to the present invention can contain at least one element selected from the group of elements (Element Group Q); preferably at least one element selected from the group consisting of Nd, Gd, La, Y, Ce, Pr, and Dy; more preferably at least one element selected from the group consisting of Nd, Gd, and La; and furthermore preferably at least one element selected from the group consisting of Nd and La.

Specifically, the rare-earth elements help the Al alloy film to be resistant to the generation of hillocks (nodular protrusions) and to increase the heat resistance. The substrate on which the Al alloy film has been deposited is subjected to the formation of a silicon nitride film (protective film) typically through CVD. In this process, applied heat at high temperatures causes thermal expansion of the Al alloy film and the substrate, but these two members are different in coefficient of thermal expansion, and this difference probably causes hillocks (nodular protrusions). However, the presence of the rare-earth element suppresses the generation of the hillocks. In addition, the presence of the rare-earth element also improves the corrosion resistance.

To exhibit these activities effectively, the Al alloy film has a total content of the rare-earth elements of preferably 0.1 atomic percent or more and more preferably 0.2 atomic percent or more. However, the rare-earth elements, if present in an excessively high total content, may increase the electrical resistance of the Al alloy film itself after the heat treatment. For this reason, the upper limit of the total content of the rare-earth elements is preferably 2 atomic percent, and more preferably 1 atomic percent.

The Al alloy film preferably further contains Cu in a content of 0.1 to 6 atomic percent in order to further stabilize the contact resistance. As is described above, Cu element forms fine precipitates and thereby contributes to reduction and stabilization of the contact resistance. To exhibit these activities effectively, the Cu content is preferably 0.1 atomic percent or more. However, Cu, if present in an excessively high content, may cause the precipitates to have larger sizes (to become coarse), and this may increase, for example, the variation in contact resistance depending on the cleaning time. For this reason, the upper limit of the Cu content is herein set to be 6 atomic percent. A preferred upper limit of the Cu content is 2.0 atomic percent.

The ratio [Cu/(Ni+Co)] of the Cu content to the total content of Ni and Co is preferably 0.5 or less, for further stabilizing the contact resistance. This is because a high ratio of the Cu content to the total content of Ni and Co may cause the precipitates, which contribute typically to the stabilization of the contact resistance, to be coarse and thereby may increase the variation of the contact resistance. The ratio [Cu/(Ni+Co)] is more preferably 0.3 or less. Although not critical from the viewpoint of stabilization of the contact resistance, the lower limit of the ratio is preferably approximately 0.1 or more, in consideration typically of reduction of the contact resistance and size reduction of the precipitates.

The Al alloy film is desirably deposited through sputtering using a sputtering target (hereinafter also referred to as “target”). This is because the sputtering can easily give a thin film which is superior in in-plane uniformity of component and in film thickness to thin films formed by ion plating, electron beam vapor evaporation, or vacuum deposition.

To deposit an Al alloy film according to the present invention through sputtering, an Al alloy sputtering target having the same composition with that of the desired Al alloy film is preferably used to allow the Al alloy film to have a desired chemical composition without composition deviation.

Specifically, a preferred Al alloy sputtering target to deposit the Al alloy film through sputtering is an Al alloy sputtering target which contains Ge in a content of 0.05 to 2.0 atomic percent; at least one element selected from the Element Group X consisting of Ni, Ag, Co, Zn, and Cu; and at least one element selected from the Element Group Q consisting of rare-earth elements in a content of 0.02 to 2 atomic percent, with the remainder including Al and inevitable impurities and which has the same composition with the composition of the desired Al alloy film. The resulting Al alloy film can have the desired chemical composition without composition deviation.

To deposit, through the sputtering, the Al alloy film according to the preferred first embodiment to be directly connected to the transparent conductive film, the target may be an Al alloy sputtering target which contains Ge in a content of 0.05 to 1.0 atomic percent; at least one element selected from the group consisting of Ni, Ag, Co, and Zn (as Group X element) in a content of 0.03 to 2.0 atomic percent; and at least one element selected from the group consisting of rare-earth elements (Group Q element) in a content of 0.05 to 0.5 atomic percent, with the remainder including Al and inevitable impurities and which has the same composition with that of the desired Al alloy film.

According to the chemical composition of the Al alloy film to be deposited, the sputtering target may be one containing at least one element selected from the group consisting of Nd, Gd, La, Y, Ce, Pr, and Dy as the rare-earth element; one having a ratio [(Group X element)/(Group Q element)] of the content (atomic percent) of the Group X element to the content (atomic percent) of the Group Q element of more than 0.1 and 7 or less; or one containing Cu in a content of 0.1 to 0.5 atomic percent.

To deposit the Al alloy film according to the preferred second embodiment through the sputtering, the target may be an Al alloy sputtering target which contains Ge in a content of 0.2 to 2.0 atomic percent; at least one element selected from, of the Element Group X, the group consisting of Ni, Co, and Cu; and at least one element selected from the Element Group Q consisting of rare-earth elements in a content of 0.02 to 1 atomic percent, with the remainder including Al and inevitable impurities and which has the same composition with that of the desired Al alloy film.

The sputtering target is preferably a target containing at least one element selected from the Element Group X in a content of 0.02 to 0.5 atomic percent.

Also preferred are a target containing Ag in a content of 0.1 to 0.6 atomic percent; and a target containing In and/or Sn in a content of 0.02 to 0.5 atomic percent.

Where necessary, the contents of elements belonging to the Element Group X preferably satisfies following Expression (1):

10(Ni+Co+Cu)≦5 (1)

wherein “Ni”, “Co”, and “Cu” represent the contents (in units of atomic percent) of the respective elements in the Al alloy film.

When the Al alloy film contains at least one of Ag, In, and Sn, the contents of the elements preferably satisfy following Expression (2). The left-hand side in following Expression (2) is more preferably 2 atomic percent or less, and furthermore preferably 1 atomic percent or less.

2Ag+10(In+Sn+Ni+Co+Cu)≦5 (2)

In Expression (2), “Ag”, “In”, “Sn”, “Ni”, “Co”, and “Cu” represent the contents (in units of atomic percent) of the respective elements in the Al alloy film.

To deposit the Al alloy film according to the preferred third embodiment through the sputtering, the target may be an Al alloy sputtering target which contains Ge in a content of 0.1 to 2 atomic percent; at least one element selected from, of the Element Group X, the group consisting of Ni and Co; and at least one element selected from the Element Group Q consisting of rare-earth elements in a content of 0.02 to 2 atomic percent, with the remainder including Al and inevitable impurities and which has the same composition with that of the desired Al alloy film.

The target can be processed into an arbitrary shape, such as rectangular plate shape, circular plate shape, or donut-plate shape, according to the shape and structure of the sputtering equipment.

Exemplary processes to prepare the target include a process of preparing ingots composed of an Al-based alloy through melting/casting, powder sintering, or spray forming, and forming the ingots into the target; and a process of preparing a preform (intermediate prior to a final compact body) composed of the Al-based alloy and densifying the preform into a compact body as the target.

For precipitating the Ge-containing precipitates having a major axis of 20 nm or more in the specific amount in the Al alloy film, it is effective to subject the Al alloy film deposited through the sputtering to a heat treatment under the following conditions. Specifically, it is preferred to subject the Al alloy film to the heat treatment by holding at a temperature of 230° C. or higher (more preferably 250° C. or higher, and furthermore preferably 280° C. or higher) and 290° C. or lower for 30 minutes or more (more preferably 60 minutes or more, and furthermore preferably 90 minutes or more) so as to grow the precipitates sufficiently. In this treatment, the Al alloy film is placed in a heat-treating furnace at room temperature, raised in temperature at a temperature rise rate of 5° C. per minute, held at a desired temperature for a certain time, cooled to 100° C., and retrieved from the furnace.

Though not critical, the upper limit of the heating temperature in the heat treatment is about 350° C., and the upper limit of the heating holding time is about 120 minutes, both from the viewpoint of productivity.

In this treatment, it is preferred to precipitate Ge-containing precipitates in a large amount so as to avoid precipitation of Al-(Group X element) precipitates and to ensure direct contact (DC) properties, because the Al-(Group X element) precipitates (such as Al₃Ni) adversely affect the corrosion resistance of the Al alloy film, as described above. It should be noted that the Ge-containing precipitates start to precipitate at around 250° C., whereas Al₃Ni precipitates start to precipitate at a temperature of higher than 290° C. and 300° C. or lower. Specifically, an abrupt rise in heating temperature to higher than 290° C. may increase the amount of the Al-(Group X element) precipitates.

Under these circumstances, the heat treatment for precipitating the Ge-containing precipitates in a large amount is preferably performed while holding the Al alloy film at a temperature within the range of 250° C. or higher 290° C. or lower, regardless of the highest achieving temperature. The Ge-containing precipitates contain the Group X element even in a trace amount, thereby the precipitation of the Ge-containing precipitates in a large amount at a heating temperature of 290° C. or lower leads to the consumption of the Group X element in excess, to thereby impede the precipitation of the Al-(Group X element) precipitates. For this reason, the rate of temperature rise to the heating-holding temperature is 10° C. per minute or less, preferably 5° C. per minute or less, and furthermore preferably 3° C. per minute or less. Thus, the temperature is preferably raised gradually over a relatively long time. The heating atmosphere is preferably a vacuum atmosphere or an atmosphere of inert gas such as nitrogen or argon.

The precipitation of the Al-(Group X element) precipitates can be suppressed by controlling the rate of temperature rise as described above. However, in a preferred embodiment of the Al alloy film according to the present invention, the upper limit of the content of the Group X element is controlled to be 2.0 atomic percent, and according to this embodiment, the precipitation of the Al-(Group X element) precipitates can be suppressed without controlling the rate of temperature rise in particular.

For suppressing the precipitation of coarse precipitates and for allowing the Al alloy film to have a number density of precipitates having a grain size of more than 100 nm of 1 or less per 10⁻⁶ cm², it is preferred to control the base pressure during evacuation in the film deposition so as to have a residual oxygen partial pressure of 1×10⁻⁸ Torr or more (more preferably 2×10⁻⁸ Torr or more). This allows nuclei serving as origins of precipitates to be finely dispersed in the Al alloy.

In a preferred embodiment of the present invention, the Ge-containing precipitates present in the Al alloy film are directly connected to the transparent conductive film, for further surely reducing the contact resistance.

The present invention also includes a display device including at least one thin-film transistor including the Al alloy film. A display device as an embodiment thereof is a display device, in which the Al alloy film is used as a source electrode and/or drain electrode and as a signal line in the thin-film transistor, and the drain electrode is directly connected to the transparent conductive film. The Al alloy film according to the present invention can also be used as a gate electrode and scanning line. In this case, the source electrode and/or drain electrode and the signal line are composed of an Al alloy film having the same composition with that of the gate electrode and scanning line.

Components constituting the TFT array substrate and those constituting the display device, other than the Al alloy film, are not particularly limited, as long as being generally used ones.

The transparent conductive film for use in the present invention is preferably an indium tin oxide (ITO) film or indium zinc oxide (IZO) film.

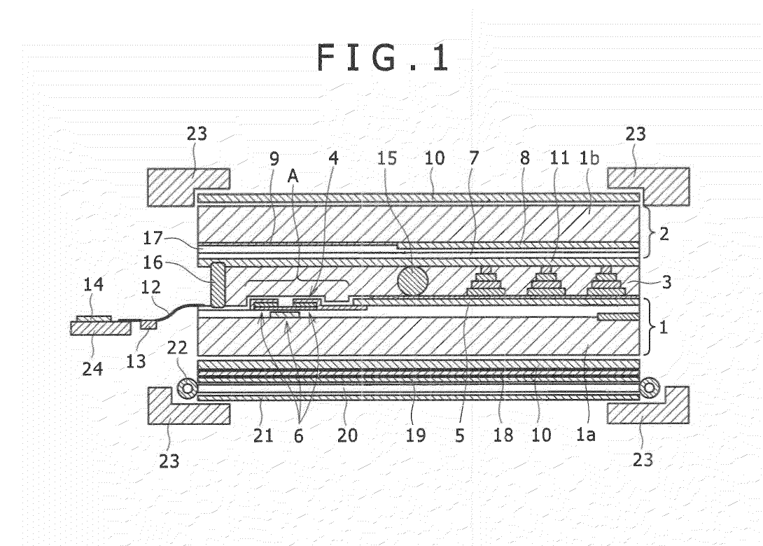

Some preferred embodiments of the display device according to the present invention will be illustrated below, with reference to the attached drawings. Hereinafter the preferred embodiments will be illustrated while taking liquid crystal display devices (for example one illustrated in FIG. 1, the details thereof will be explained later) having an amorphous silicon TFT array substrate or polysilicon TFT array substrate as representative examples. It should be noted, however, that these are never construed to limit the scope of the present invention.

### First Embodiment

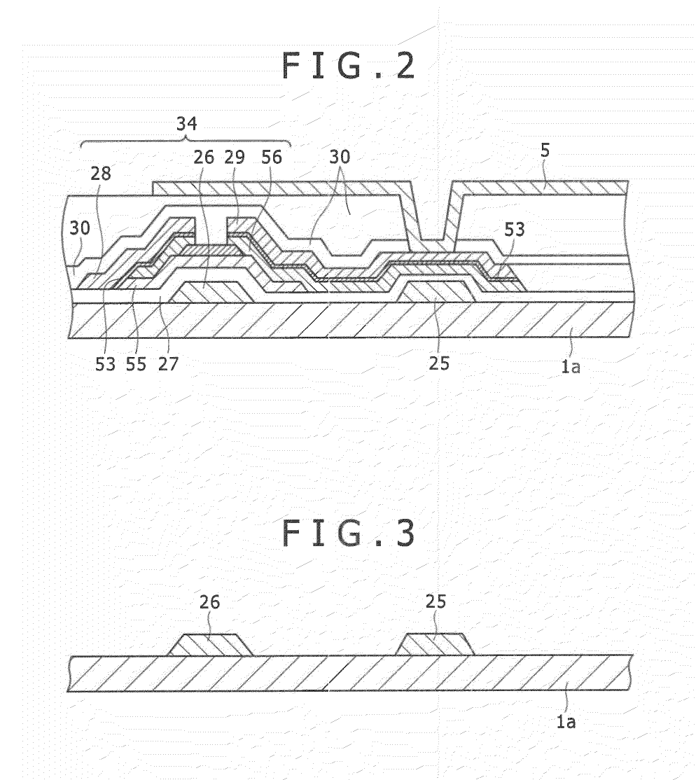

An amorphous silicon TFT array substrate as an embodiment will be illustrated in detail below, with reference to FIG. 2.

FIG. 2 is an enlarged view of the essential parts A of FIG. 1 (an embodiment of the display device according to the present invention) and is a schematic cross sectional view illustrating a preferred embodiment of the TFT array substrate (bottom-gate type) of the display device according to the present invention.

In this embodiment, the Al alloy film is used as source-drain electrodes/signal line (34) and gate electrode/scanning line (25, 26). A customary TFT array substrate includes barrier metal layers on the scanning line 25, on the gate electrode 26, and on or below the signal line 34 (source electrode 28 and drain electrode 29). In contrast, the TFT array substrate according to this embodiment does not need the barrier metal layers.

Specifically, this embodiment allows the Al alloy film serving as the drain electrode 29 of the TFT to be directly connected to a transparent pixel electrode 5 without the interposition of the barrier metal layer. Even the TFT array substrate according to this embodiment can exhibit satisfactory TFT characteristic properties equal to or higher than those of the customary TFT array substrate.

Next, an embodiment of a fabrication method for the amorphous silicon TFT array substrate in FIG. 2 according to the present invention will be illustrated with reference to FIGS. 3 to 10. The thin-film transistor herein is an amorphous silicon TFT using hydrogenated amorphous silicon as a semiconductor layer. Components in FIGS. 3 to 10 have the same referential signs with those in FIG. 2.

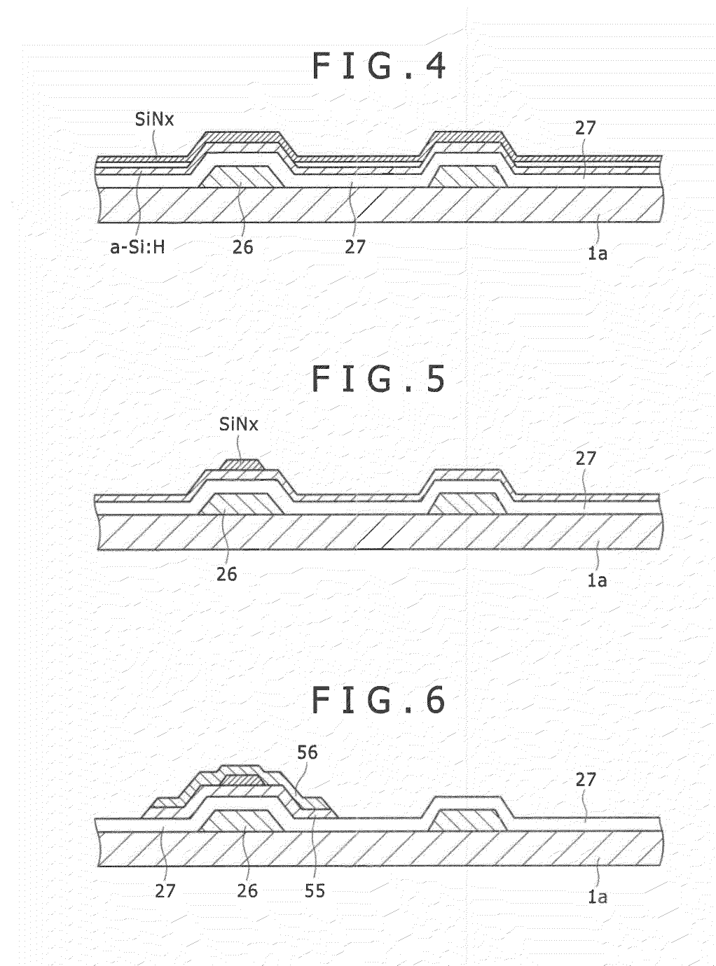

Initially, an Al alloy film having a thickness of about 200 nm is deposited on a glass substrate (transparent substrate) 1a through sputtering. The film deposition through sputtering is performed at a temperature of 150° C. The Al alloy film is pattered to form a gate electrode 26 and a scanning line 25 (see FIG. 3). In this process, the circumferential edges of the Al alloy film constituting the gate electrode 26 and scanning line 25 are preferably etched and thereby tapered at an angle of about 30° to 40°, so as to yield better coverage of a gate insulating film 27 in a process shown in after-mentioned FIG. 4.

Next, with reference to FIG. 4, a silicon oxide film (SiOx) having a thickness of about 300 nm is deposited as a gate insulating film 27 typically through plasma CVD. The film deposition through plasma CVD is herein performed at a temperature of about 350° C. Subsequently, a hydrogenated amorphous silicon film (a-Si—H) having a thickness of about 50 nm and a silicon nitride film (SiNx) having a thickness of about 300 nm are sequentially deposited on the gate insulating film 27 typically through plasma CVD.

Subsequently, the silicon nitride film (SiNx) is patterned through back exposure using the gate electrode 26 as a mask, to form a channel protective film (see FIG. 5). Further thereon, a phosphorus-doped n⁺-type hydrogenated amorphous silicon film (n⁺ a-Si—H) 56 having a thickness of about 50 nm is deposited, and the non-doped hydrogenated amorphous silicon film (a-Si—H) 55 and the n⁺-type hydrogenated amorphous silicon film (n⁺ a-Si—H) 56 are patterned as illustrated in FIG. 6.

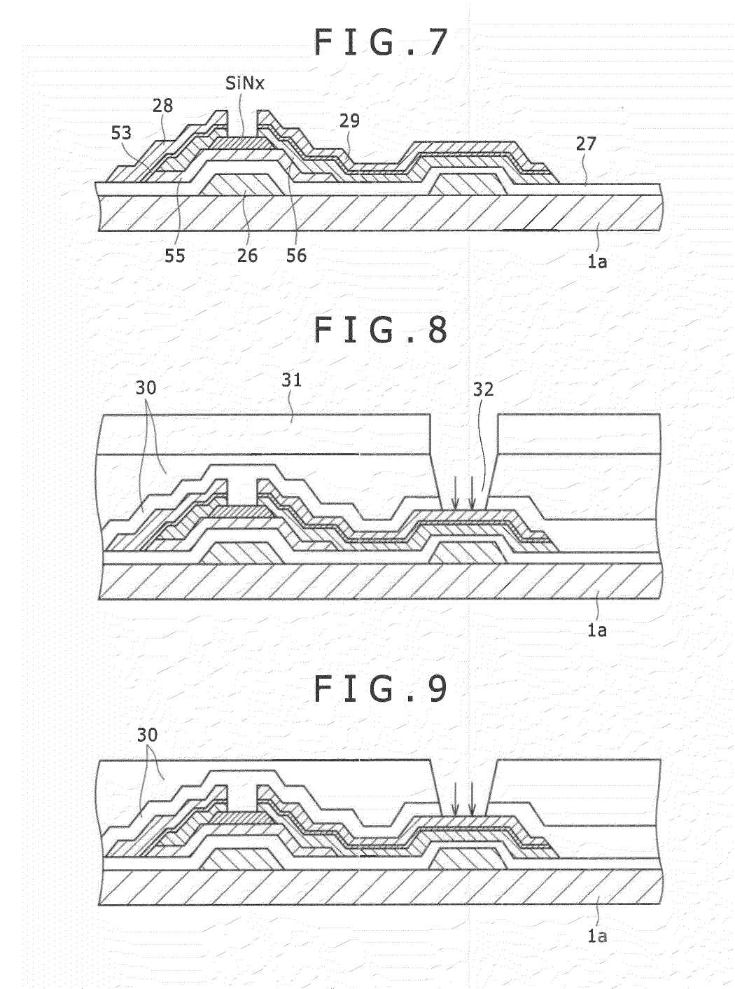

Next, a barrier metal layer (Mo film) 53 having a thickness of about 50 nm and an Al alloy film having a thickness of about 300 nm are sequentially deposited thereon through sputtering. The film deposition through sputtering is herein performed at a temperature of 150° C. In this process, the base pressure during evacuation in the film deposition of the Al alloy film is preferably controlled so as to give a residual oxygen partial pressure of 1×10⁻⁸ Torr or more, to thereby allow nuclei serving as origins of precipitates to be finely dispersed in the Al alloy. Next, patterning is performed as illustrated in FIG. 7, to form a source electrode 28 integrated with a signal line, and a drain electrode 29 to be directly connected to a transparent pixel electrode 5. In this process, the work is preferably subjected to a heat treatment of holding at 230° C. or higher for 3 minutes or longer, to precipitate Ge-containing precipitates having a major axis of 20 nm or more in a certain amount. Next, the n⁺-type hydrogenated amorphous silicon film (n⁺ a-Si—H) 56 on the channel protective film (SiNx) is removed by dry etching using the source electrode 28 and drain electrode 29 as masks.

Next, with reference to FIG. 8, a silicon nitride film 30 having a thickness of about 300 nm is deposited as a protective film typically using plasma CVD equipment. The film deposition in this process is performed at a temperature of typically about 250° C. Next, after forming a photoresist 31 on the silicon nitride film 30, the silicon nitride film 30 is patterned to form a contact hole 32 through the silicon nitride film 30 typically by dry etching. Simultaneously, a contact hole (not shown) is formed at the edge of the panel in a portion above the gate electrode to be connected to a tape automated bonding tape (TAB tape).

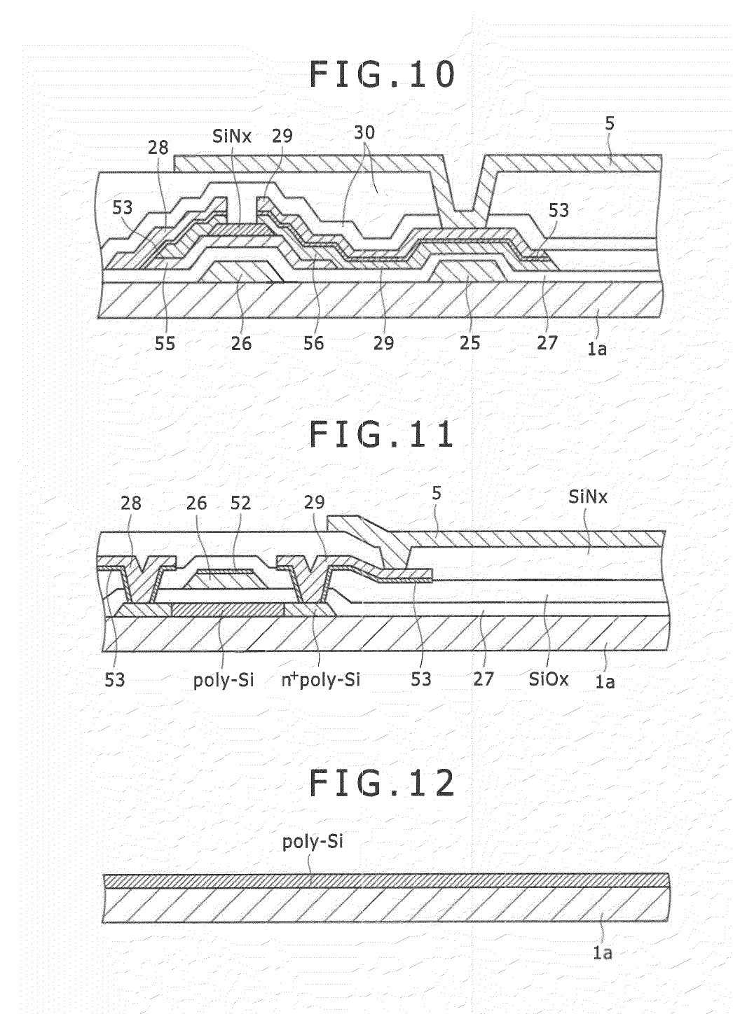

Next, after performing an ashing process typically with oxygen plasma, the photoresist 31 is removed typically with an amine stripper, as illustrated in FIG. 9. Finally, with reference to FIG. 10, an ITO film, for example, having a thickness of about 40 nm is deposited and patterned through wet etching to form a transparent pixel electrode 5. This process is done typically within a storage time (about 8 hours). Simultaneously, the ITO film in a portion at the edge of the panel in the gate electrode to be connected to the TAB tape is patterned for bonding with the TAB tape. Thus, a TFT array substrate 1 is completed.

In the resulting TFT array substrate, the drain electrode 29 and the transparent pixel electrode 5 are directly connected to each other.

Although the ITO film is used as the transparent pixel electrode 5 in the above example, an IZO film is also usable. Likewise, a polysilicon is usable as the active semiconductor layer instead of the amorphous silicon (see after-mentioned Second Embodiment).

Using the TFT array substrate thus obtained, the liquid crystal display device illustrated in FIG. 1 is completed typically according to the following method.

Initially, a polyamide, for example, is applied to the surface of the above-produced TFT array substrate 1, dried, and rubbed to form an alignment layer.

Independently, a counter substrate 2 is formed in the following manner. A light shielding film 9 is formed on a glass substrate by patterning, for example, chromium (Cr) into a matrix. Next, resinous red, green, and blue color filters 8 are formed in gaps in the light shielding film 9. A transparent conductive film such as an ITO film is arranged as a common electrode 7 on the light shielding film 9 and the color filters 8 to thereby form a counter electrode. A polyamide, for example, is applied to the outermost layer of the counter electrode, dried, and rubbed to form an alignment layer 11.

Next, TFT array substrate 1 and the counter substrate 2 are arranged so that the alignment layer 11 of the counter substrate 2 faces the alignment layer of the TFT array substrate 1; and the TFT array substrate 1 and the counter substrate 2 are affixed with each other by a sealant 16 made typically of a resin, except for a liquid-crystal filling port. In this process, a gap between the two substrates, i.e., the TFT array substrate 1 and the counter substrate 2 is held substantially constant typically with the interposition of spacers 15.

The empty cell thus obtained is placed in a vacuum, the pressure thereof is gradually returned to the atmospheric pressure while the filling port is immersed in a liquid crystal, thereby the liquid crystal material containing liquid crystal molecules is charged into the empty cell to form a liquid crystal layer, and the filling port is then end-sealed. Finally, reflector plates 10 are affixed to both outer sides of the cell to complete a liquid crystal display.

Next, with reference to FIG. 1, a drive circuit 13 for driving the liquid crystal display device is electrically connected to the liquid crystal display and is arranged on the side or backside of the liquid crystal display. Subsequently, the liquid crystal display is held by a holding frame 23 having an opening serving as a display surface of the liquid crystal display, a backlight 22 serving as a surface light source, a light guide panel 20, and another holding frame 23, to complete the liquid crystal display device.

### Second Embodiment

A polysilicon TFT array substrate as another embodiment will be illustrated in detail with reference to FIG. 11.

FIG. 11 is a schematic cross sectional view illustrating a preferred embodiment of a top-gate type TFT array substrate relating to the present invention.

This embodiment differs from above-mentioned First Embodiment mainly in using a polysilicon instead of the amorphous silicon as the active semiconductor layer and in using a top-gate type TFT array substrate instead of the bottom-gate type TFT array substrate. Specifically, the polysilicon TFT array substrate according to this embodiment as illustrated in FIG. 11 differs from the amorphous silicon TFT array substrate in FIG. 2 in that the active semiconductor film is composed of a non-phosphorus-doped polysilicon film (poly-Si) and a polysilicon film implanted with phosphorus or arsenic ions (n⁺ poly-Si). The signal line is formed so as to intersect with the scanning line via an interlayer insulating film (SiOx).

The TFT array substrate according to this embodiment also does not need barrier metal layers to be formed on the source electrode 28 and the drain electrode 29.

Next, an embodiment of a fabrication method for the polysilicon TFT array substrate according to this embodiment of the present invention as in FIG. 11 will be illustrated with reference to FIGS. 12 to 18. The thin-film transistor herein is a polysilicon TFT using a polysilicon film (poly-Si) as a semiconductor layer. Components in FIGS. 12 to 18 are indicated with the same referential signs as those in FIG. 11.

Initially, a silicon nitride film (SiNx) having a thickness of about 50 nm, a silicon oxide film (SiOx) having a thickness of about 100 nm, and a hydrogenated amorphous silicon film (a-Si—H) having a thickness of about 50 nm are sequentially deposited on a glass substrate 1a typically through plasma CVD at a substrate temperature of about 300° C. Next, a heat treatment (about 470° C. for about 1 hour) and a laser annealing are performed for converting the hydrogenated amorphous silicon film (a-Si—H) into a polysilicon. After performing dehydrogenation, laser beams at an energy of about 230 mJ/cm² are applied to the hydrogenated amorphous silicon film (a-Si—H) typically using excimer laser annealing equipment, to form a polysilicon film (poly-Si) having a thickness of about 0.3 μm (FIG. 12).

Next, with reference to FIG. 13, the polysilicon film (poly-Si) is patterned typically through plasma etching. Next, with reference to FIG. 14, a silicon oxide film (SiOx) having a thickness of about 100 nm is deposited as a gate insulating film 27. An Al alloy film having a thickness of about 200 nm and a barrier metal layer (Mo thin film) 52 having a thickness of about 50 nm are deposited on the gate insulating film 27 typically through sputtering, and these films are patterned typically through plasma etching. This gives a gate electrode 26 integrated with a scanning line.

Subsequently, with reference to FIG. 15, a mask is formed from a photoresist 31, and phosphorus ions, for example, are doped at an energy of about 50 keV to a density of 1×10¹⁵/cm² typically using ion implantation equipment, to form a n⁺-type polysilicon film (n⁺ poly-Si) in part of the polysilicon film (poly-Si). Next, the photoresist 31 is stripped, and the work is subjected to a heat treatment at typically about 500° C. to diffuse phosphorus.

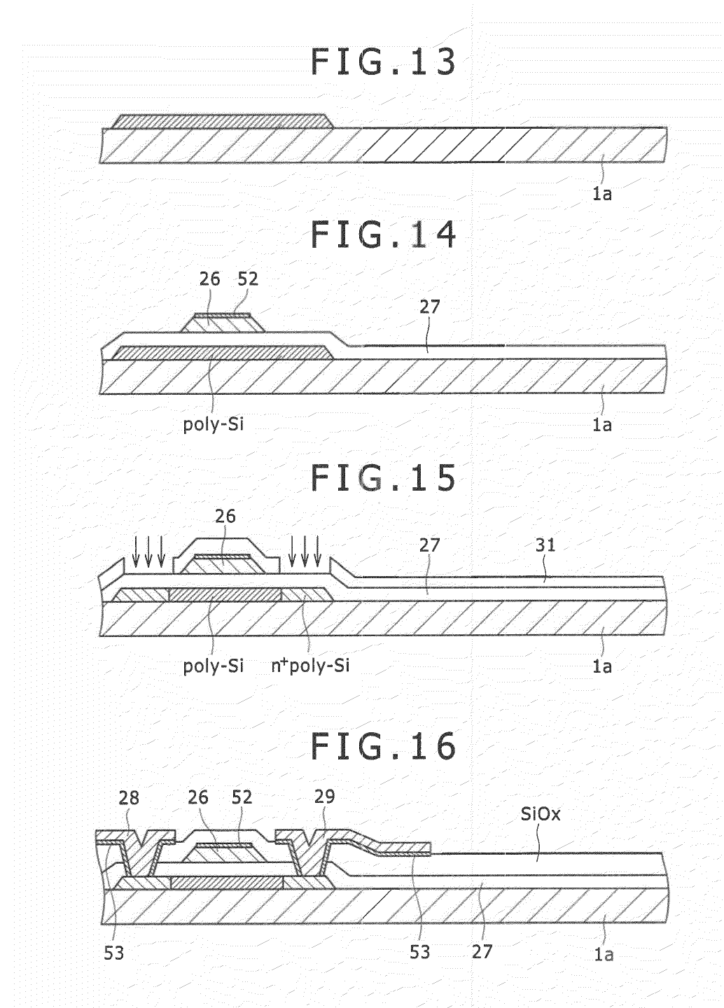

Next, with reference to FIG. 16, a silicon oxide film (SiOx) having a thickness of about 500 nm is deposited as an interlayer insulating film typically using plasma CVD equipment at a substrate temperature of about 250° C., and the silicon oxide films as the interlayer insulating film (SiOx) and the gate insulating film 27 are dry-etched using a mask which has been patterned with a photoresist, to form contact holes in the same manner as above. Next, a barrier metal layer (Mo film) 53 having a thickness of about 50 nm and an Al alloy film having a thickness of about 450 nm are deposited through sputtering and are then patterned to form a source electrode 28 and a drain electrode 29 each integrated with a signal line. In this process, the base pressure during evacuation in the film deposition of the Al alloy film is preferably controlled so as to give a residual oxygen partial pressure of 1×10⁻⁸ Torr or more, to thereby allow nuclei serving as origins of precipitates to be finely dispersed in the Al alloy. In this process, the work is preferably subjected to a heat treatment of holding at 230° C. or higher for 3 minutes or longer, to precipitate Ge-containing precipitates having a major axis of 20 nm or more in a certain amount. The source electrode 28 and the drain electrode 29 are respectively connected via the contact holes to the n⁺-type polysilicon film (n⁺ poly-Si).

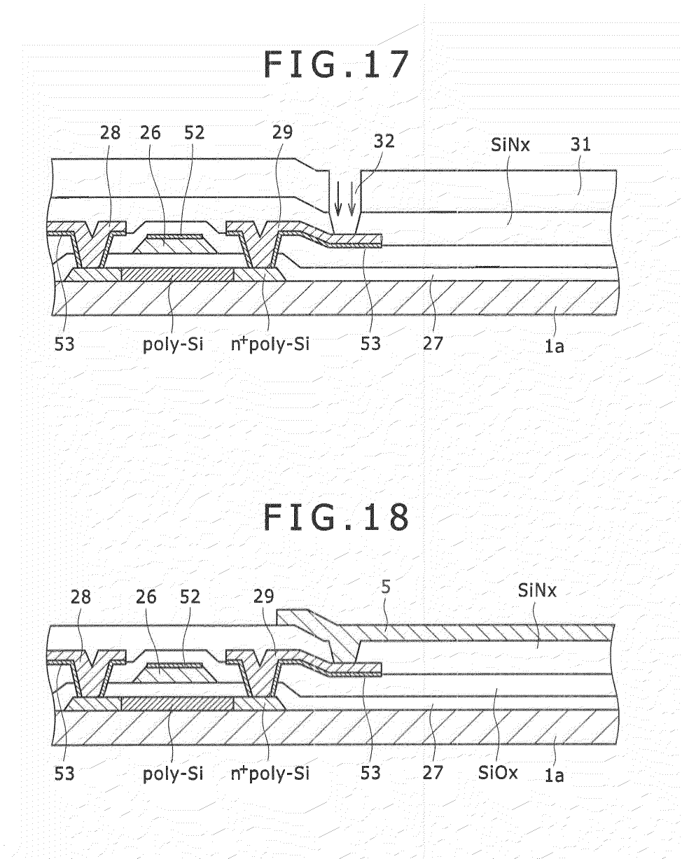

Next, with reference to FIG. 17, a silicon nitride film (SiNx) having a thickness of about 500 nm is deposited as an interlayer insulating film typically using plasma CVD equipment at a substrate temperature of about 250° C. After forming a photoresist 31 on the interlayer insulating film, the silicon nitride film (SiNx) is patterned to form a contact hole 32 in the silicon nitride film (SiNx) typically through dry etching.

Next, with reference to FIG. 18, after performing an ashing process typically with oxygen plasma, the photoresist is stripped typically with an amine stripper by the procedure of First Embodiment, an ITO film is deposited, patterned through wet etching, and thereby yields a transparent pixel electrode 5.

In the resulting polysilicon TFT array substrate, the drain electrode 29 is directly connected to the transparent pixel electrode 5.

Next, the work is annealed at typically about 250° C. for about 1 hour for the stabilization of characteristic properties of the transistor. Thus, a polysilicon TFT array substrate is completed.

The TFT array substrate according to Second Embodiment and the liquid crystal display device including the TFT array substrate can give advantageous effects as with those of the TFT array substrate according to First Embodiment.

Using the resulting TFT array substrate, a liquid crystal display device as illustrated in FIG. 1 is completed in the same manner as with the TFT array substrate according to First Embodiment.

Such a display device including the Al alloy film according to the present invention may be produced by general processes for display devices, except for adding the specific heating treatment for the formation of a specific Ge-enriched area to any of a series of film deposition processes for the deposition of the Al alloy film, the SiN film (insulating film), and the ITO film. Specifically, the fabrication may be performed with reference typically to the fabrication methods described in PTL 1 and 6.

### Examples

The present invention will be illustrated in further detail with reference to several experimental examples below. It should be noted, however, that these examples are never intended to limit the scope of the present invention; various alternations and modifications may be made without departing from the scope and spirit of the present invention and all fall within the scope of the present invention.

### Experimental Example 1

A series of Al alloy films having a film thickness of 300 nm and having different alloy compositions given in Table 1 and Table 2 was deposited through direct-current (DC) magnetron sputtering using the load-lock sputtering equipment CS-200 supplied by ULVAC, Inc. under the following conditions:

Substrate: cleaned glass substrate (Eagle 2000 supplied by Corning Inc.)

DC Power: total 500 W

Substrate Temperature: 25° C. (room temperature)

Ambient Gas: Ar

Ar Gas Pressure: 2 mTorr

The base pressure during evacuation in the film deposition was controlled so as to give a residual oxygen partial pressure of 1×10⁻⁸ Torr or more, to thereby finely disperse nuclei serving as origins of precipitates in the Al alloy. The Al alloy films having the different alloy compositions were deposited using two or more of two-component targets composed of Al and alloy elements of different types.

The contents of the respective alloy elements in the Al alloy films used in Experimental Example 1 were determined through inductively coupled plasma (ICP) emission spectrometry.

Next, the specimens after the film deposition were subjected to a heat treatment (by heating at 330° C. in a nitrogen flow for 30 minutes) to give precipitates. This heat treatment simulated a thermal hysteresis applied during the fabrication of a TFT array substrate.

The precipitated precipitates were observed as reflected images under a scanning electron microscope (SEM), and grain sizes of respective precipitates observed as white spots (precipitates observed at an acceleration voltage of 1 keV (in the vicinity of the surface)) were calculated as a sum of the major axis and the minor axis divided by 2 [((major axis)+(minor axis))/2]. The grain size of a largest precipitate, and the number density of precipitates having a grain size of more than 100 nm (number of precipitates having a grain size of more than 100 nm present per an area of 10⁻⁶ cm²) were determined in the following manner. Specifically, the number of precipitates having a grain size of more than 100 nm observed in a view field of 125 μm long and 100 μm wide was counted using a SEM, and the number was converted into a number density per 10⁻⁶ cm².

Next, evaluations were performed in the following manner. Specifically, the number of black dots (black dot-like etching marks) observed in a 10-μm-square contact hole is preferably less than 1; and the number density of coarse precipitates having a grain size of more than 100 nm is preferably low, because the black dots (black dot-like etching marks) are generated in the vicinity of coarse precipitates having a grain size of more than 100 nm. From these viewpoints, the sizes of the precipitates as determined in the observation under the SEM were evaluated.

Next, an immersion test in an aqueous solution of an amine resist stripper was performed according to the following process, which test simulated a cleaning process with a photoresist stripper. Specifically, each sample was immersed in an amine stripper (at a solution temperature of 25° C.) having a controlled pH of 10.5 for 1 minute; immersed in an aqueous solution of the amine resist stripper (at a solution temperature of 25° C.) having a controlled pH of 9.5 for 5 minutes; and rinsed with running water for 30 seconds. Thus, a series of specimens was obtained, and the entire surface of each specimen was observed under an optical microscope at a magnification of 1000 times, and whether or not an etching mark (black dot-like etching mark) was observed in the vicinity of precipitates in one view field (one view field has a size of about 130 μm long and 100 μm wide) which had been determined as an average view field.

Specimens were evaluated according to the following criteria:

A specimen having a number density of visually observed black dots of 1 or less was rated as “A”;

A specimen having a number density of visually observed black dots of more than 1 and equal to or less than 2 was rated as “B”; and

A specimen having a number density of visually observed black dots of more than 2 was rated as “C”.

The results are shown in Table 1 and Table 2.

TABLE 1

| | | | Residual oxygen | | | Number density of | |
|---|---|---|---|---|---|---|---|
| | | Left-hand value of | content after film | Grain size | | precipitates having a grain | Rating in |
| | | Expression (2) | deposition | of largest | | size of more than 100 nm | immersion in |
| No. | Composition* of Al alloy film | (atomic percent) | (×10⁻⁸ Torr) | precipitate | | (number per 10⁻⁶ cm²) | stripper |
| 1 | Al—0.5Ge—0.7Ag—0.5Nd | 1.4 | 0.8 | 1000 | nm | 1.5 | B |
| 2 | Al—0.5Ge—0.2Ag—0.5Nd | 0.4 | 1.2 | 70 | nm | 0.01 | A |
| 3 | Al—0.5Ge—0.2Ag—0.2La | 0.4 | 1.1 | 70 | nm | 0.01 | A |
| 4 | Al—0.5Ge—0.2Ag—0.1Ti | 0.4 | 1.1 | 90 | nm | 0.13 | A |
| 5 | Al—0.5Ge—0.1Ag—0.2La | 0.2 | 1.4 | 100 | nm | 0.04 | A |
| 6 | Al—0.5Ge—0.05Ag—0.2La | 0.1 | 1.2 | 100 | nm | 1 | B |
| 7 | Al—0.5Ge—0.2Ni—0.5Nd | 2 | 1.3 | 100 | nm | 2 | B |
| 8 | Al—0.5Ge—0.1Ni—0.2La | 1 | 1.6 | 50 | nm | 0.28 | A |
| 9 | Al—0.5Ge—0.05Ni—0.2La | 0.5 | 1.4 | 60 | nm | 0.12 | A |
| 10 | Al—0.3Ge—0.1Ni—0.2La | 1 | 1.3 | 50 | nm | 0.01 | A |
| 11 | Al—1.0Ge—0.1Ni—0.2La | 1 | 1.4 | 70 | nm | 0.13 | A |
| 12 | Al—1.5Ge—0.1Ni—0.2La | 1 | 1.7 | 60 | nm | 0.2 | A |
| 13 | Al—0.5Ge—0.02Ni—0.2La | 0.2 | 1.5 | 80 | nm | 0.01 | A |
| 14 | Al—0.5Ge—0.1Co—0.2La | 1 | 1.4 | 70 | nm | 0.03 | A |
| 15 | Al—0.5Ge—0.05Co—0.2La | 0.5 | 1.6 | 80 | nm | 0.02 | A |
| 16 | Al—0.5Ge—0.02Co—0.2La | 0.2 | 1.5 | 60 | nm | 0.01 | A |
| 17 | Al—0.5Ge—0.05In—0.2La | 0.5 | 1.5 | 60 | nm | 0.06 | A |
| 18 | Al—0.5Ge—0.02In—0.2La | 0.2 | 0.7 | 100 | nm | 3.2 | C |
| 19 | Al—0.5Ge—0.1Sn—0.2La | 1 | 0.6 | 100 | nm | 4.3 | C |
| 20 | Al—0.5Ge—0.1Sn—0.5Nd | 1 | 0.7 | 100 | nm | 3.2 | C |
| 21 | Al—0.5Ge—0.05Sn—0.2La | 0.5 | 0.6 | 100 | nm | 2.5 | C |
| 22 | Al—0.5Ge—0.02Sn—0.2La | 0.2 | 0.7 | 120 | nm | 2.1 | C |
| 23 | Al—0.2Ni—0.35La | 2 | 1.3 | 280 | nm | 3 | C |

*The numerical values represent contents (atomic percent) of the respective alloy elements in the Al alloy film.

TABLE 2

| | | | Residual oxygen | | | Number density of | |
|---|---|---|---|---|---|---|---|
| | | Left-hand value of | content after film | Grain size | | precipitates having a grain | Rating in |
| | | Expression (2) | deposition | of largest | | size of more than 100 nm | immersion in |
| No. | Composition* of Al alloy film | (atomic percent) | (×10⁻⁸ Torr) | precipitate | | (number per 10⁻⁶ cm²) | stripper |
| 24 | Al—0.5Ge—0.2Ag—0.02Sn—0.5La | 0.6 | 1.5 | 80 | nm | 0.05 | A |
| 25 | Al—0.5Ge—0.05Ni—0.02Sn—0.5La | 0.7 | 0.5 | 150 | nm | 0.02 | B |
| 26 | Al—0.5Ge—0.05Ni—0.05Co—0.5La | 1 | 0.7 | 100 | nm | 3.2 | C |
| 27 | Al—0.5Ge—0.05Ni—0.05Cu—0.5La | 1 | 0.4 | 150 | nm | 0.02 | B |
| 28 | Al—0.5Ge—0.05Ni—0.2Ag—0.2La | 0.9 | 1.2 | 80 | nm | 0.02 | A |
| 29 | Al—0.5Ge—0.05Co—0.2Ag—0.2La | 0.9 | 1.7 | 60 | nm | 0.02 | A |
| 30 | Al—0.5Ge—0.05Ni—0.05Co—0.2La | 1 | 0.7 | 100 | nm | 5 | C |
| 31 | Al—0.5Ge—0.02In—0.2Ag—0.2La | 0.6 | 1.5 | 50 | nm | 0.18 | A |
| 32 | Al—0.5Ge—0.02In—0.05Ni—0.2La | 0.7 | 1.6 | 50 | nm | 0.03 | A |
| 33 | Al—0.5Ge-0.02Ing-0.05Cu—0.2La | 0.7 | 1.4 | 50 | nm | 0.05 | A |
| 34 | Al—0.5Ge—0.2Ag—0.02Sn—0.2La | 0.6 | 1.3 | 80 | nm | 0.93 | A |
| 35 | Al—0.5Ge—0.05Ni—0.02Sn—0.2La | 0.7 | 0.7 | 135 | nm | 1.32 | C |
| 36 | Al—0.5Ge—0.02Sn—0.05Cu—0.2La | 0.7 | 1.6 | 60 | nm | 0.34 | A |
| 37 | Al—0.5Ge—0.02In—0.02Sn—0.2La | 0.4 | 1.4 | 70 | nm | 0.23 | A |
| 38 | Al—0.5Ge—0.1Ni—0.05Cu—0.05Co—0.2La | 2 | 1.2 | 60 | nm | 0.04 | A |

*The numerical values represent contents (atomic percent) of the respective alloy elements in the Al alloy film.

The data in Table 1 and Table 2 demonstrate as follows. Initially, the Al alloy films containing Ge, at least one Group X element, and at least one Group Q element in specific contents and being deposited according to the recommended method can have satisfactory surfaces less suffering from coarse precipitates, and, as a result, visually show no black dots even after being exposed to the aqueous solution of amine stripper.

In contrast, the Al alloy films being deposited not according to the recommended method (namely, without controlling the base pressure during evacuation in the film deposition so as to give a residual oxygen partial pressure of 1×10⁻⁸ Torr or more) fail to have finely dispersed precipitation nuclei in the Al alloy and thereby suffer from precipitation of coarse precipitates, resulting in suffering from visible black dots when exposed to the aqueous solution of amine stripper.

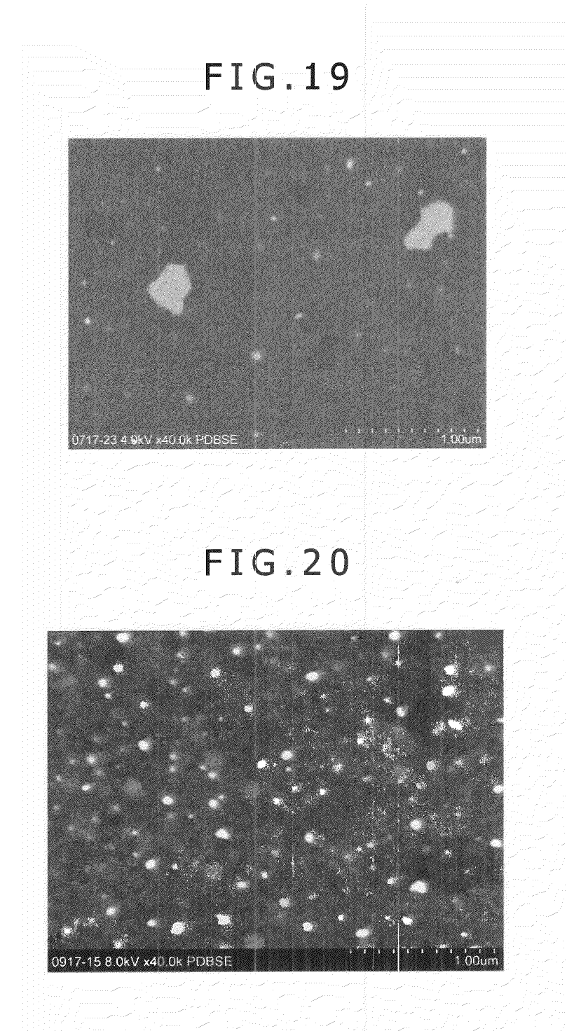

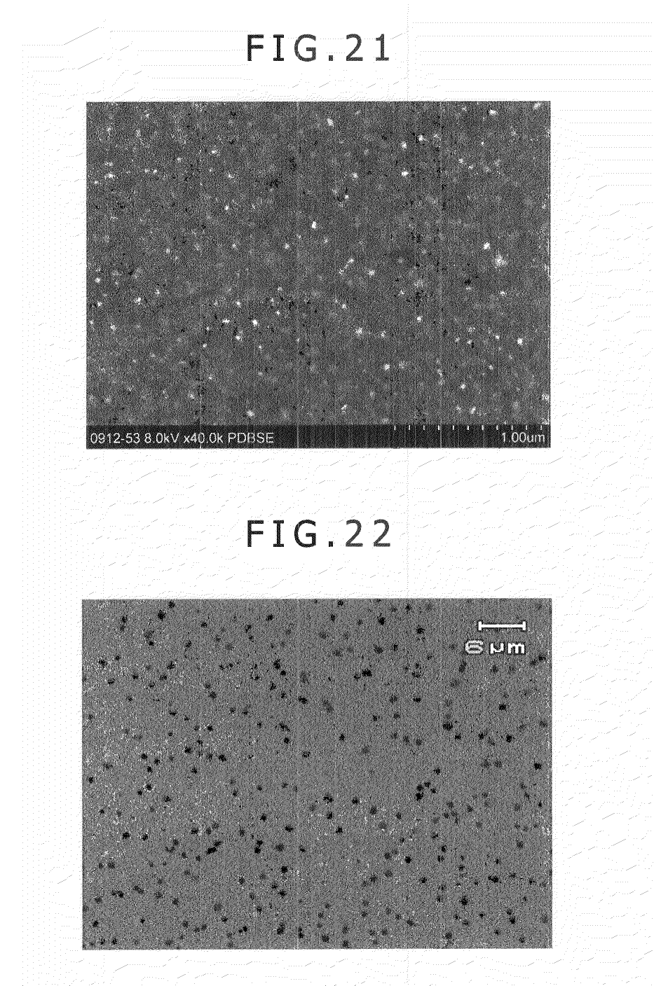

As referential examples of the observation of precipitates, photographs as reflected images, in the observation under a SEM, of Sample No. 23, No. 22, and No. 8 are shown in FIGS. 19 to 21, respectively. These photographs demonstrate as follows. Sample No. 23 (FIG. 19) having a chemical composition not satisfying the specific conditions shows coarse precipitates which are observed as white spots. In contrast, Sample No. 22 (FIG. 20) having a chemical composition satisfying the specific conditions and being deposited under the recommended conditions shows fine precipitates. Sample No. 8 (FIG. 21) containing Ni as an alloy element shows further finer precipitates than those in Sample No. 22.

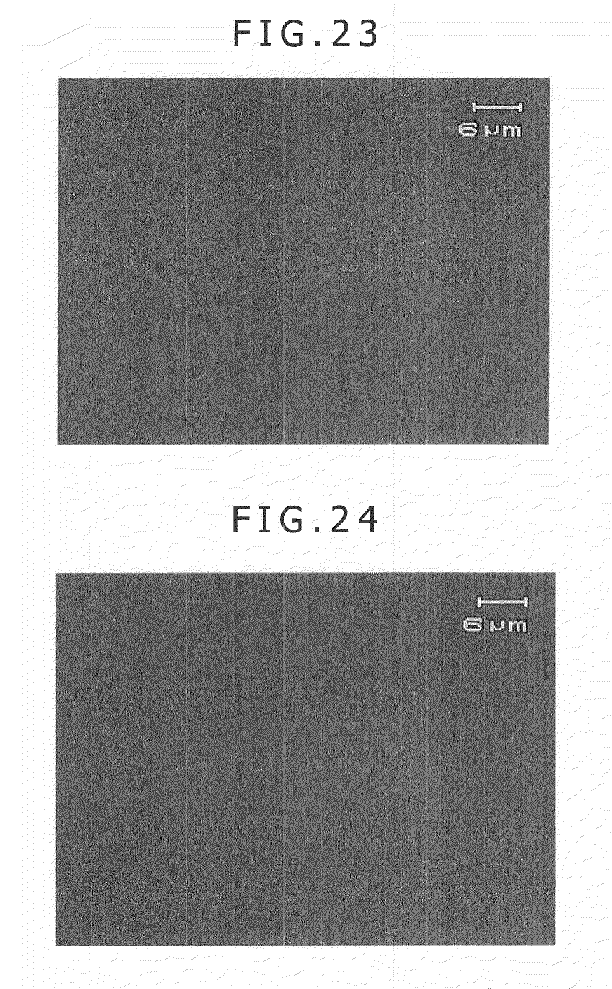

Photographs of Sample No. 23, No. 22, and No. 8 in the observation under an optical microscope after the immersion in the aqueous solution of stripper are also shown in FIGS. 22 to 24, respectively. These photographs demonstrate as follows. Sample No. 23 (FIG. 22) having coarse precipitates shows significantly outstanding black dot-like corrosion marks. In contrast, Sample No. 22 (FIG. 23) having fine precipitates shows substantially inconspicuous black dot-like corrosion marks; and Sample No. 8 (FIG. 24) shows substantially no black dot-like corrosion marks.

### Experimental Example 2

A series of Al alloy films having a film thickness of 300 nm and having different alloy compositions given in Table 3 was deposited through DC magnetron sputtering. The sputtering was performed using a glass substrate (Eagle 2000 supplied by Corning Inc.) as a substrate and argon as an ambient gas at a pressure of 266 mPa (2 mTorr) and a substrate temperature of 25° C. (room temperature).

The deposition of the Al alloy films having the different alloy composition was performed using, each as a sputtering target, Al alloy targets being prepared by vacuum melting and having the different compositions.

The contents of the respective alloy elements in the Al alloy films used in Experimental Example 2 were determined through inductively coupled plasma (ICP) emission spectrometry.

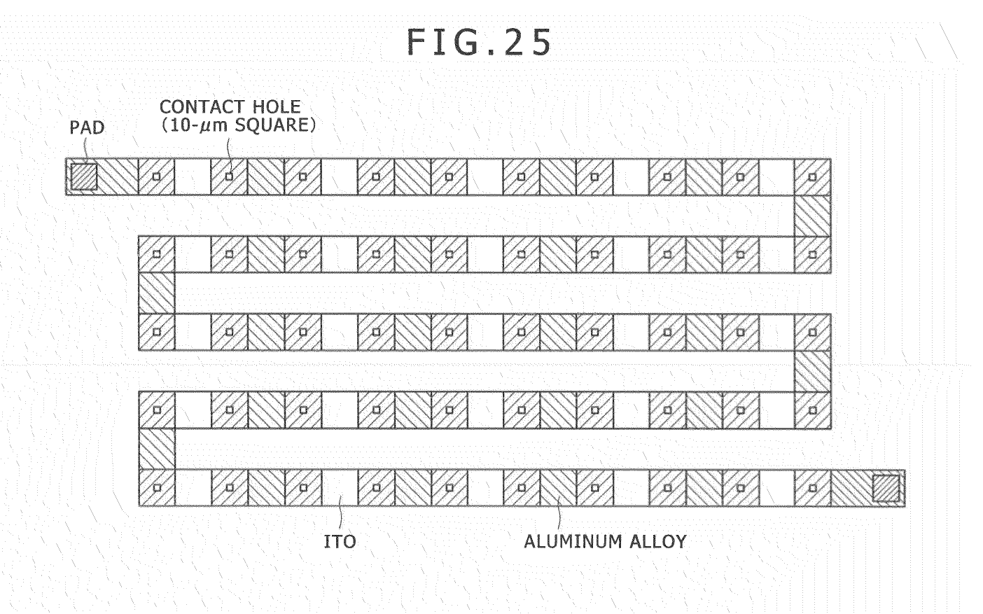

The above-deposited Al alloy films were subjected sequentially to photolithography and etching to form an electrode pattern shown in FIG. 25. Next, the Al alloy films were subjected to a heat treatment to precipitate alloy elements as precipitates. In the heat treatment, the works were placed in a heat-treating furnace in a N₂ atmosphere, heated to 330° C. over 30 minutes, held at 330° C. for 30 minutes, cooled to 100° C. or lower, and retrieved from the furnace. Subsequently, a SiN film was deposited thereon at a temperature of 330° C. in CVD equipment. In addition, the works were subjected to photolithography and to etching in reactive ion etching (RIE) equipment to form a contact hole in the SiN film. After the formation of the contact hole, the works were subjected to oxygen plasma ashing with a barrel asher to remove reaction products and then soaked in an aqueous solution of the amine resist stripper “TOK 106” supplied by Tokyo Ohka Kogyo Co., Ltd. to remove the residual resist completely. In this process, aluminum was reduced slightly, because a rinsing solution became a basic solution containing the amine and water during rinsing with water. Next, an ITO film (transparent conductive film) was deposited through sputtering under conditions mentioned below, and subjected to photolithography and patterning to thereby form a contact chain pattern (FIG. 25) including fifty contact holes having a size of 10-μm square connected in series.

### (Deposition Conditions for Ito Film)

Ambient Gas: argon

Pressure: 106.4 mPa (0.8 mTorr)

Substrate Temperature: 25° C. (room temperature)

The total resistance (contact resistance) of the contact chain was determined by contacting probes with pads at both ends of the contact chain pattern and measuring I-V characteristics. The measured total resistance was then converted into a contact resistance per one contact. The sizes (major axes) of Ge-containing precipitates, and the number density of Ge-containing precipitates having a major axis of 20 nm or more were determined by using reflected electron images obtained under a scanning electron microscope. Specifically, the number of Ge-containing precipitates having a major axis of 20 nm or more in one view field (100 μm²) was counted, this counting was repeated for a total of three view fields, the three counts were averaged, and the average was defined as the number density of the Ge-containing precipitates. The major axes of the respective Ge-containing precipitates in the three view fields were measured, and one having the largest major axis was defined as a largest Ge-containing precipitate, and the major axis thereof was recorded. Elements contained in the precipitates were identified through transmission electron microscopy-energy dispersive X-ray spectrometry (TEM-EDX). The results are shown in Table 3.

Independently, for some of the compositions given in Table 3, Al alloy films having a film thickness of 300 nm were deposited and subjected to a heat treatment to precipitate alloy elements as precipitates in the same manner as above, and these were used as specimens for the measurement of number density of corrosion marks. In the heat treatment, the works were placed in a heat-treating furnace in a N₂ atmosphere, heated to 330° C. over 30 minutes, held at 330° C. for 30 minutes, cooled to 100° C. or lower, and retrieved from the furnace. The number densities of corrosion marks of the resulting specimens were measured in the following manner. The results are shown in Table 3.

### (Measurement of Number Density of Corrosion Marks)

The specimens were subjected to a cleaning process with an amine resist stripper (“TOK 106” supplied by Tokyo Ohka Kogyo Co., Ltd.). The cleaning process was performed sequentially by immersing in a stripper aqueous solution having a controlled pH of 10.5 for 1 minute; immersing in a stripper aqueous solution having a controlled pH of 9.5 for 5 minutes; rinsing with pure water; and drying. The specimens after the cleaning process were observed under an optical microscope at a magnification of 1000 times, the number densities of corrosion marks (number of black dots (corrosion marks originated from precipitates) per unit area) were measured.

TABLE 3

| | | | | Major axis | Number density | | Number |
|---|---|---|---|---|---|---|---|
| | | Ratio of Group X | Major axis | of largest | of Ge-containing | | density of |
| | | element to Group Q | of largest | Ge-containing | precipitates | | corrosion |
| | | element [(Group X | Ge-containing | precipitate | having a major axis | Contact | marks |
| | | element)/(Group Q | precipitate | A: ≧20 nm, | of 20 nm or more | resistance*² | (number/ |
| No. | Composition*¹ of Al alloy film | element)] | (nm) | B: <20 nm | (number per 100 μm²) | (Ω) | 100 μm²) |
| 1 | Al—0.02Ni—0.5Ge—0.2La | 0.1 | 10 | B | 0 | 5 × 10³ | 0 |
| 2 | Al—0.1Ni—0.5Ge—0.2La | 0.5 | 40 | A | 100 | 110 | |
| 3 | Al—0.1Ni—0.5Ge—0.5La | 0.2 | 100 | A | 270 | 120 | |
| 4 | Al—0.1Ni—0.5Ge—0.5Nd | 0.2 | 120 | A | 330 | 110 | 0 |
| 5 | Al—0.2Ni—0.5Ge—0.2La | 1.0 | 30 | A | 170 | 62 | 0.4 |
| 6 | Al—0.2Ni—0.5Ge—0.5La | 0.4 | 100 | A | 300 | 80 | |
| 7 | Al—0.2Ni—0.5Ge—0.5Nd | 0.4 | 140 | A | 310 | 74 | |
| 8 | Al—2Ni—0.5Ge—0.2La | 10 | 25 | A | 1210 | 64 | 10.6 |
| 9 | Al—0.4Ni—0.5Ge—0.1Cu—0.2La | 2.0 | 30 | A | 220 | 73 | |
| 10 | Al—0.4Ni—0.5Ge—0.3Cu—0.2La | 2.0 | 30 | A | 230 | 115 | |
| 11 | Al—0.4Ni—0.5Ge—0.5Cu—0.2La | 2.0 | 30 | A | 260 | 102 | |
| 12 | Al—0.4Ni—0.8Ge—0.1Cu—0.2La | 2.0 | 30 | A | 360 | 86 | |
| 13 | Al—0.4Ni—0.8Ge—0.3Cu—0.2La | 2.0 | 30 | A | 400 | 98 | 5.1 |
| 14 | Al—0.2Ni—0.35La | 0.6 | — | — | 0 | 350 | |
| 15 | Al—0.08Ge—0.3La | 0.0 | 10 | B | 0 | 150 × 10³ | |
| 16 | Al—0.2Ni—0.03Ge—0.3La | 0.7 | 10 | B | 0 | 1030 | |
| 17 | Al—0.5Co—0.5Ge—0.3La | 1.7 | 25 | A | 240 | 220 | |
| 18 | Al—1Ag—0.5Ge—0.2La | 5.0 | 25 | A | 600 | 280 | |
| 19 | Al—1Zn—0.5Ge—0.2La | 5.0 | 25 | A | 530 | 290 | |
| 20 | Al—0.03Ni—0.5Ge—0.2Nd | 0.2 | 35 | A | 90 | 290 | 0 |
| 21 | Al—0.1Ni—0.5Ge—0.2Nd | 0.5 | 110 | A | 200 | 60 | 0.1 |
| 22 | Al—0.1Ni—0.5Ge—0.3Nd | 0.3 | 140 | A | 250 | 70 | 0 |
| 23 | Al—0.1Ni—0.5Ge—0.4Nd | 0.3 | 130 | A | 270 | 90 | 0 |

*¹The numerical values represent contents (atomic percent) of the respective alloy elements in the Al alloy film.
*²Value determined by measuring total resistance in the chain of fifty contacts and converting the same into a contact resistance per one contact; a specimen having a contact resistance of 500 Ω or less is rated as having a low contact resistance.

The data given in Table 3 demonstrate as follows. First of all, Al alloy films, as containing at least one Group X element such as Ni; Ge; and at least one rare-earth element (Group Q element) in specific contents, can include Ge-containing precipitates having a major axis of 20 nm or more in a specific amount or more and, as a result, can show a significantly low direct contact resistance with the ITO (transparent pixel electrode), namely, can sufficiently and reliably achieve a low contact resistance.

In addition, Al alloy films containing Cu can also include the Ge-containing precipitates in a specific amount or more and can have a lower contact resistance.

In contrast, Al alloy films containing no Ge or containing Ge but in an insufficient content fail to include Ge-containing precipitates having a major axis of 20 nm or more in a specific amount or more and fail to achieve a low contact resistance. In addition, Al alloy films containing no Group X element such as Ni or containing a Group X element such as Ni but in an insufficient content fail to ensure Ge-containing precipitates having a major axis of 20 nm or more in a sufficient amount and fail to have a low contact resistance.

Of the elements consisting of Ni, Ag, Co, and Zn, the addition of Ni allows the Al alloy films to have a further lower contact resistance.

The Al-(0.2 atomic percent Ni)-(0.5 atomic percent Ge)-(0.5 atomic percent La) alloy film has an electric resistivity of 4.7 μΩ·cm after the heat treatment at 250° C. for 30 minutes; but the Al-(0.2 atomic percent Ni)-(1.2 atomic percent Ge)-(0.5 atomic percent La) alloy film has a higher electric resistivity of 5.5 μΩ·cm after the heat treatment at 250° C. for 30 minutes, indicating that such an Al alloy film containing Ge in an excessively high content shows a higher electric resistivity.

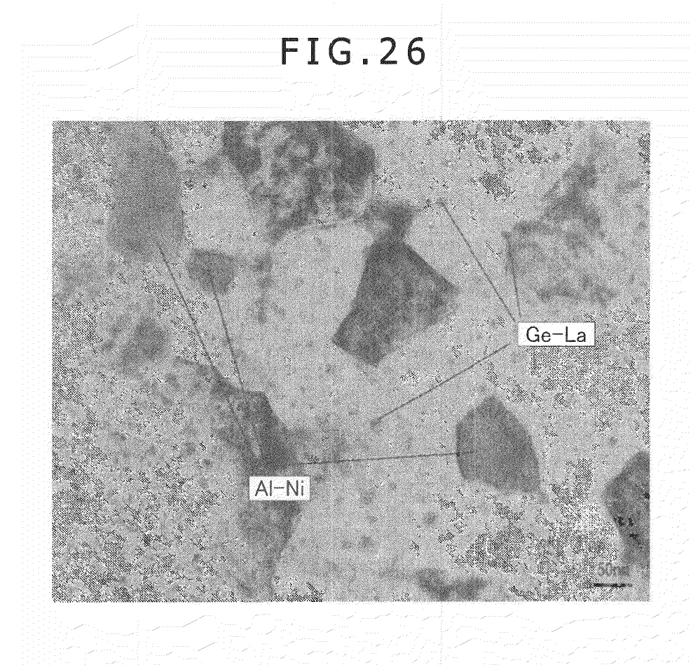

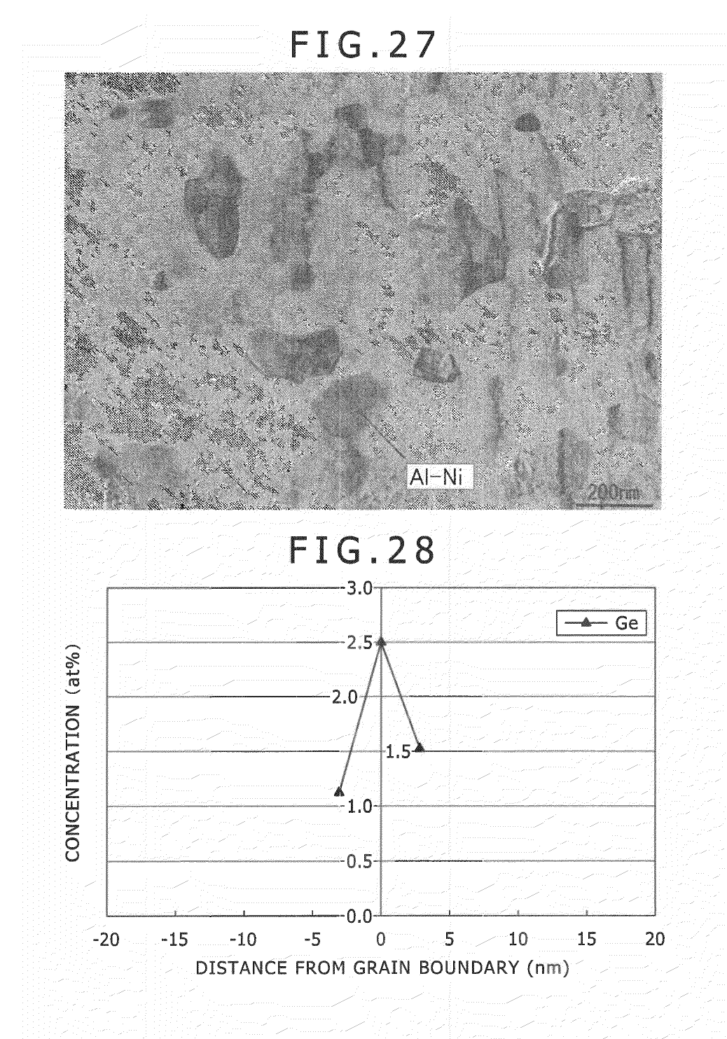

As referential examples of the observation of precipitates, photographs, taken in the observation under a TEM, of Sample No. 5 and No. 14 are respectively shown in FIG. 26 and FIG. 27. FIG. 26 demonstrates that the Al alloy film (Sample No. 5) satisfying the conditions specified in the present invention includes dispersed Ge-containing precipitates having a major axis of 20 nm or more; but in contrast, FIG. 27 demonstrates that the Al alloy film (Sample No. 14) containing no Ge includes only relatively coarse precipitates such as Al—Ni precipitates.

The data in Table 3 further demonstrate that Sample Nos. 4, 5, 13, 20 to 23 each having a ratio of the Group X element to the Group Q element in the Al alloy film satisfying the preferred condition in the present invention (more than 0.1 and 7 or less) have a number density of corrosion marks of 5.1 or less per 100 μm², indicating that they also excel in corrosion resistance. The Al alloy films have a decreasing number density of corrosion marks with a decreasing ratio [(Group X element)/(Group Q element)], and among them, Sample Nos. 4, 5, and 20 to 23 having a ratio [(Group X element)/(Group Q element)] of 1.0 or less have a number density of corrosion marks controlled to be approximately zero (0) per 100 μm².

### Experimental Example 3

A series of Al alloy films having a film thickness of 300 nm and having different alloy compositions given in Tables 4 and 5 was deposited through DC magnetron sputtering. The sputtering was performed using a glass substrate (Eagle 2000 supplied by Corning Inc.) as a substrate and argon as an ambient gas at a pressure of 2 mTorr and a substrate temperature of 25° C. (room temperature).

The Al alloy films were then patterned. Next, a SiN film having a thickness of about 300 nm was deposited as an insulating layer, and the works were subjected to the heat treatments shown in Tables 4 and 5. Next, the works were subjected sequentially to resist coating, exposure, development, etching of the SiN film, and stripping and cleaning of the resist so as to form contact holes. Next, an ITO film was deposited as a transparent pixel electrode. The deposition of the transparent pixel electrode (ITO film) was performed using argon as an ambient gas under conditions at a pressure of 0.8 mTorr and a substrate temperature of 25° C. (room temperature).

The deposition of the Al alloy film was performed using, as a sputtering target, Al alloy targets having different compositions and being prepared by vacuum melting.

The Ge concentrations of the Al alloy films were measured through ICP emission spectrometry. The Ge concentrations at the grain boundary of the aluminum matrix were determined by preparing thin-film samples for the observation under a TEM from specimens after the heat treatment and measuring the Ge concentrations through TEM-EDX. Specifically, the samples were prepared by thinning the specimens so that the surface layer (surface on which the ITO film is to be deposited) thereof remained. Images of the samples were obtained from the specimen surface layer side under a field emission transmission electron microscope (FE-TEM) (HF-2200 supplied by Hitachi, Ltd.) at a magnification of 900000 times. An example of the images is shown in FIG. 29 (FIG. 29 is a miniature of the image and is indicated at a different magnification). As is shown in FIG. 29, a quantitative analysis of the chemical composition was performed on a line substantially orthogonal to the grain boundary with NSS Energy Dispersive X-ray Spectrometer (EDX) supplied by Noran Instruments, Inc., and the concentration of Ge enriched at the grain boundary of the aluminum matrix was measured.

Using the above-prepared Al alloy films, the electric resistivity of each Al alloy film itself after the heat treatment, and the direct contact resistance (contact resistance with the ITO film) upon direct connection of the Al alloy film to the transparent pixel electrode (ITO film) were measured according to the following methods, respectively.

(1) Electric Resistivity of Al Alloy Film Itself after Heat Treatment

A 10-μm wide line-and-space pattern was formed on each Al alloy film, and the electric resistivity was measured according to a four-terminal method. The electric resistivity of the Al alloy film itself after the heat treatment was rated according to the following criteria:

### (Rating Criteria)

A: less than 5.0 μΩ·cm

B: 5.0 μΩ·cm or more

(2) Direct Contact Resistance with Transparent Display Electrode

In this Experimental Example, the direct contact resistance was investigated with a focus on the direct contact resistance when cleaning using a stripper was performed for durations of 10 to 50 seconds shorter than those in customary methods (typically about 3 to about 5 minutes), so as to determine usefulness of the Al alloy films according to the present invention (in particular, capability of providing a low contact resistance independent of the cleaning time using a stripper).

Initially, the Al alloy films were subjected to a cleaning process with a basic aqueous solution containing an amine photoresist and water for different cleaning times given in Tables 4 and 5. The cleaning process was performed as simulating the cleaning process of the photoresist stripper. Specifically, each Al alloy film was immersed in a prepared aqueous solution of the amine resist stripper “TOK 106” supplied by Tokyo Ohka Kogyo Co., Ltd. having a controlled pH of 10 (at a solution temperature of 25° C.) for the cleaning times give in Tables 4 and 5.

The contact resistance between the Al alloy film after the immersion and a transparent pixel electrode being directly connected to each other was measured in the following manner. Initially, a transparent pixel electrode (ITO; indium tin oxide containing indium oxide and 10 percent by mass of tin oxide) was formed into a Kelvin pattern (contact hole size: 10-μm square) illustrated in FIG. 30. Next, the Al alloy film was subjected to a four-terminal measurement, in which a current was applied between the ITO film and the Al alloy film, and the voltage drop between the ITO film and the Al alloy film was measured with other terminals. Specifically, with reference to FIG. 30, a current I was applied between I1-I2, a voltage V between V1-V2 was monitored, and the direct contact resistance R of the contact C was determined according to the equation: R=(V2−V1)/I2. The direct contact resistance with the ITO film was rated according to the following criteria:

### (Rating Criteria)

o: less than 1000Ω

x: 1000Ω or more

The results are also shown in Tables 4 and 5. Of the results, those using Al—Ni—Ge alloy films are shown in Table 4; and those using Al—Co—Ge alloy films are shown in Table 5.

TABLE 4

| | | | | | | | Ge concen- | Ge concen- | | | | | | |
|---|---|---|---|---|---|---|---|---|---|---|---|---|---|---|
| | | | | | | | tration | tration | | | | | | |
| | | | | | | | (atomic | (atomic | | | | | | |
| | | | | Group Q | | | percent) | percent) | | Heat treatment | | Striper | Contact | Electric |
| | Ni | Ge | Cu | element | Ge/ | Cu/ | of Al | of grain | Ratio | Temper- | | cleaning | resis- | resis- |
| | (atomic | (atomic | (atomic | (atomic | (Ni + | (Ni + | alloy film | boundary | [(2)/ | ature | Time | time | tance | tance |
| No. | percent) | percent) | percent) | percent) | Co) | Co) | (matrix) (1) | (2) | (1)] | (° C.) | (minute) | (sec) | (Ω) | of film |
| 1 | 0.2 | 0.5 | | | 2.5 | | 0.5 | 1.3 | 2.6 | 330 | 30 | 25 | 82 | A |
| 2 | | | | | | | 0.5 | 1.3 | 2.6 | | | 50 | 74 | A |
| 3 | 0.2 | 0.5 | | La = 0.2 | 2.5 | | 0.5 | 2.5 | 5.0 | 330 | 10 | 25 | 113 | A |
| 4 | | | | | | | 0.5 | 2.5 | 5.0 | | | 50 | 64 | A |
| 5 | 0.6 | 1.0 | | La = 0.2 | 1.7 | | 1.0 | 3.6 | 3.6 | 330 | 15 | 25 | 587 | A |
| 6 | | | | | | | 1.0 | 3.6 | 3.6 | | | 50 | 89 | A |
| 7 | 1.6 | 0.5 | | La = 0.2 | 0.3 | | 0.5 | 2.4 | 4.8 | 330 | 10 | 10 | 480 | A |
| 8 | | | | | | | 0.5 | 2.4 | 4.8 | | | 25 | 68 | A |
| 9 | | | | | | | 0.5 | 2.4 | 4.8 | | | 50 | 41 | A |
| 10 | 0.2 | 0.5 | 0.5 | La = 0.2 | 2.5 | 2.5 | 0.5 | 1.4 | 2.8 | 330 | 10 | 10 | 780 | A |
| 11 | | | | | | | 0.5 | 1.4 | 2.8 | | | 25 | 198 | A |
| 12 | 0.4 | 0.5 | 0.5 | La = 0.2 | 1.3 | 1.3 | 0.5 | 1.3 | 2.6 | 330 | 10 | 25 | 393 | A |
| 13 | | | | | | | 0.5 | 1.3 | 2.6 | | | 50 | 99 | A |
| 14 | 0.4 | 0.5 | 0.1 | La = 0.2 | 1.3 | 0.3 | 0.5 | 1.5 | 3.0 | 300 | 10 | 10 | 90 | A |
| 15 | | | | | | | 0.5 | 1.5 | 3.0 | | | 25 | 85 | A |
| 16 | | | | | | | 0.5 | 1.5 | 3.0 | | | 50 | 76 | A |
| 17 | 0.6 | 0.4 | 0.1 | La = 0.2 | 0.7 | 0.2 | 0.4 | 1.4 | 3.5 | 300 | 10 | 10 | 520 | A |
| 18 | | | | | | | 0.4 | 1.4 | 3.5 | | | 25 | 155 | A |
| 19 | | | | | | | 0.4 | 1.4 | 3.5 | | | 50 | 93 | A |
| 20 | 1.6 | 0.5 | 0.5 | La = 0.2 | 0.3 | 0.3 | 0.5 | 1.1 | 2.2 | 330 | 10 | 10 | 420 | A |
| 21 | | | | | | | 0.5 | 1.1 | 2.2 | | | 50 | 40 | A |
| 22 | 0.6 | 0.8 | 0.1 | La = 0.5 | 1.3 | 0.2 | 0.8 | 2.1 | 2.6 | 330 | 12 | 25 | 169 | A |
| 23 | | | | | | | 0.8 | 2.1 | 2.6 | | | 50 | 76 | A |
| 24 | 0.02 | 0.5 | | La = 0.2 | 25.0 | | 0.5 | 2.8 | 5.6 | 330 | 10 | 25 | 9000 | A |
| 25 | | | | | | | 0.5 | 2.8 | 5.6 | | | 50 | 4000 | A |
| 26 | 8 | 0.5 | | La = 0.2 | 0.1 | | 0.5 | 1.2 | 2.4 | 330 | 10 | 25 | 60 | B |
| 27 | | | | | | | 0.5 | 1.2 | 2.4 | | | 50 | 51 | B |
| 28 | 0.6 | 0.4 | 0.1 | La = 0.2 | 0.7 | 0.2 | 0.4 | 0.6 | 1.5 | | | 25 | ≧10000 | A |
| 29 | | | | | | | 0.4 | 0.7 | 1.8 | 100 | 10 | 25 | ≧10000 | A |

TABLE 5

| | | | | | | | Ge concen- | Ge concen- | | | | | | |
|---|---|---|---|---|---|---|---|---|---|---|---|---|---|---|
| | | | | | | | tration | tration | | | | | | |
| | | | | | | | (atomic | (atomic | | | | | | |
| | | | | Group Q | | | percent) | percent) | | Heat treatment | | Striper | Contact | Electric |
| | Ni | Ge | Cu | element | Ge/ | Cu/ | of Al | of grain | Ratio | Temper- | | cleaning | resis- | resis- |
| | (atomic | (atomic | (atomic | (atomic | (Ni + | (Ni + | alloy film | boundary | [(2)/ | ature | Time | time | tance | tance |
| No. | percent) | percent) | percent) | percent) | Co) | Co) | (matrix) (1) | (2) | (1)] | (° C.) | (minute) | (sec) | (Ω) | of film |
| 1 | 0.2 | 1.0 | | La = 0.2 | 5.0 | | 1.0 | 2.7 | 2.7 | 330 | 15 | 25 | 162 | A |
| 2 | | | | | | | 1.0 | 2.7 | 2.7 | | | 50 | 118 | A |
| 3 | 0.4 | 0.5 | 0.5 | Nd = 0.2 | 1.3 | 1.3 | 0.5 | 2.6 | 5.2 | 330 | 10 | 25 | 786 | A |
| 4 | | | | | | | 0.5 | 2.6 | 5.2 | | | 50 | 201 | A |
| 5 | 0.4 | 0.5 | 0.1 | La = 0.2 | 1.3 | 0.3 | 0.5 | 2.7 | 5.4 | 330 | 10 | 25 | 170 | A |
| 6 | | | | | | | 0.5 | 2.7 | 5.4 | | | 50 | 152 | A |
| 7 | 0.6 | 0.02 | 0.5 | La = 0.2 | 0.03 | 0.8 | 0.02 | 0.02 | 1.0 | 330 | 10 | 25 | ≧10000 | A |
| 8 | | | | | | | 0.02 | 0.02 | 1.0 | | | 50 | ≧10000 | A |
| 9 | | | | | | | 0.02 | 0.02 | 1.0 | | | 125 | 120 | A |
| 10 | 0.6 | 4.0 | | La = 0.2 | 6.7 | | 4.0 | 15 | 3.8 | 330 | 10 | 25 | 70 | B |
| 11 | | | | | | | 4.0 | 15 | 3.8 | | | 50 | 39 | B |

Data in these tables demonstrate as follows.

Initially, the data given in Table 4 demonstrate that the Al alloy films of Sample Nos. 1 and 2 each having a Ni content, a Ge content, and a Ge-segregation ratio satisfying the conditions specified in the present invention, and the Al alloy films of Sample Nos. 3 to 23 further containing a rare-earth element and/or Cu in a preferred content each show a low contact resistance and have a low electric resistivity of themselves, even though they have been subjected to a cleaning process using a stripper performed for a shorter time than that in a customary process.

In contrast, the Al alloy films of Sample Nos. 24 and 25 containing Ni in an insufficient content show a higher contact resistance. The Al alloy films of Sample No. 26 and 27 containing Ni in an excessively high content and having a ratio of the Ge content to the total content of Ni and Co out of the preferred range in the present invention have a higher electric resistivity of the Al alloy films themselves.

The Al alloy films of Sample No. 28 (customary example without heating treatment) and of Sample No. 29 (example which underwent heating at a low temperature) have not undergo the predetermined heating treatment, thereby do not satisfy the conditions specified in the present invention, and have a ratio of the Ge content to the total content of Ni and Co out of the preferred range in the present invention. These Al alloy films show a higher contact resistance when subjected to a cleaning process using a stripper performed for a short time.

The tendency as in the data given in Table 4 is also observed in the data given in Table 5, in which Al—Co—Ge alloy films containing Co instead of Ni were used. Specifically, the Al alloy films of Sample Nos. 1 and 2 each having a Co content, a Ge content, and a Ge-segregation ratio satisfying the conditions specified in the present invention, and the Al alloy films of Sample Nos. 3 to 6 further containing a rare-earth element and/or Cu in a preferred content have a contact resistance and an electrical resistance of the Al alloy films themselves both controlled to be low, even though they have been subjected to a cleaning process using a stripper performed for a shorter time than that in a customary process.

In contrast, Al alloy films containing Ge in an insufficient content have a low Ge-segregation ratio and have a ratio of the Ge content to the total content of Ni and Co out of the preferred range in the present invention. These Al alloy films show a sufficiently low contact resistance when subjected to a cleaning process using a stripper for a time of about 125 seconds (Sample No. 9) as in a conventional cleaning process, but show a higher contact resistance when subjected to a cleaning process using a stripper for a shorter time of 25 seconds and 50 seconds (Sample Nos. 7 and 8).

Al alloy films of Sample Nos. 10 and 11 containing Ge in an excessively high content show a higher electric resistivity of the films themselves.

While the present invention has been described in detail with reference to the specific embodiments thereof, it is obvious to those skilled in the art that various changes and modifications can be made in the present invention without departing from the spirit and scope of the present invention.

The present application is based on Japanese Patent Application No. 2008-284893 filed on Nov. 5, 2008, Japanese Patent Application No. 2008-284894 filed on Nov. 5, 2008, and Japanese Patent Application No. 2009-004687 filed on Jan. 13, 2009, the entire contents of which are incorporated herein by reference.

### INDUSTRIAL APPLICABILITY

An Al alloy film according to an embodiment of the present invention can be directly connected to a transparent pixel electrode (transparent conductive film, oxide conductive film) without the interposition of a barrier metal layer and sufficiently and reliably has a low contact resistance. An Al alloy film for a display device according to another embodiment excels also in corrosion resistance (stripper resistance). In addition, an Al alloy film for a display device according to yet another embodiment also excels in heat resistance. The Al alloy films according to the present invention, when adopted to a display device, eliminate the need of the barrier metal layer. Accordingly, the Al alloy films according to the present invention can give a display device which has excellent productivity, which is available at low cost, and which has high performance.

### REFERENCE SIGNS LIST

1 TFT array substrate
2 counter substrate
3 liquid crystal layer
4 thin-film transistor (TFT)
5 transparent pixel electrode (transparent conductive film)
6 interconnection
7 common electrode
8 color filter
9 light shielding film
10 reflector plate
11 alignment layer
12 TAB tape
13 drive circuit
14 control circuit
15 spacer
16 sealant
17 protective film
18 diffuser panel
19 prism sheet
20 light guide panel
21 reflector plate
22 backlight
23 holding frame
24 printed circuit board
25 scanning line
26 gate electrode
27 gate insulating film
28 source electrode
29 drain electrode
30 protective film (silicon nitride film)
31 photoresist
32 contact hole
33 amorphous silicon channel film (active semiconductor film)
34 signal line
52, 53 barrier metal layer
55 non-doped hydrogenated amorphous silicon film (a-Si—H)
56 n⁺-type hydrogenated amorphous silicon film (n⁺ a-Si—H)

1. An Al alloy film comprising:
germanium (Ge) in a content of 0.05 to 2.0 atomic percent;
at least one element selected from the Element Group X consisting of Ni, Ag, Co, Zn, and Cu; and
at least one element selected from the Element Group Q consisting of rare-earth elements in a content of 0.02 to 2 atomic percent,
wherein the Al alloy film comprises at least one of a Ge-containing precipitate and a Ge-enriched area.

2. The Al alloy film according to claim 1,
wherein the Al alloy film comprises:
Ge in a content of 0.05 to 1.0 atomic percent;
at least one element selected from, of the Element Group X, the group consisting of Ni, Ag, Co, and Zn in a content of 0.03 to 2.0 atomic percent; and
at least one element selected from the Element Group Q consisting of rare-earth elements in a content of 0.05 to 0.5 atomic percent, and
wherein the Al alloy film comprises Ge-containing precipitates having a major axis of 20 nm or more in a number density of 50 or more per 100 μm².

3. The Al alloy film according to claim 2, wherein the rare-earth elements are selected from the group consisting of Nd, Gd, La, Y, Ce, Pr, and Dy.

4. The Al alloy film according to claim 2, further comprising, of the Element Group X, Cu in a content of 0.1 to 0.5 atomic percent.

5. The Al alloy film according to claim 2, wherein the Al alloy film has a ratio [(Group X element)/(Group Q element)] of more than 0.1 and 7 or less, wherein the ratio is the ratio of the content (atomic percent) of the at least one element selected from the Element Group X (Group X element) to the content (atomic percent) of the at least one element selected from the Element Group Q (Group Q element).

6. The Al alloy film according to claim 2, wherein the Al alloy film comprises Ge in a content of 0.3 to 0.7 atomic percent.

7. The Al alloy film according to claim 2, wherein the Ge-containing precipitates in the Al alloy film are directly connected to the transparent conductive film.

8. The Al alloy film according to claim 1,
wherein the Al alloy film comprises:
Ge in a content of 0.2 to 2.0 atomic percent;
at least one element selected from, of the Element Group X, the group consisting of Ni, Co, and Cu; and
at least one element selected from the Element Group Q consisting of rare-earth elements in a content of 0.02 to 1 atomic percent, and
wherein the Al alloy film comprises a number density of precipitates having a grain size of more than 100 nm of 1 or less per 10⁻⁶ cm².

9. The Al alloy film according to claim 8, wherein the Al alloy film comprises at least one element selected from the Element Group X in a content of 0.02 to 0.5 atomic percent.

10. The Al alloy film according to claim 8, wherein the content of the at least one element selected from the Element Group X satisfies following Expression (1):
10(Ni+Co+Cu)≦5 (1)
wherein “Ni”, “Co”, and “Cu” in Expression (1) represent the contents (in units of atomic percent) of the respective elements in the Al alloy film.

11. The Al alloy film according to claim 1, wherein the Al alloy film comprises:
Ge in a content of 0.1 to 2 atomic percent; and
at least one element selected from, of the Element Group X, the group consisting of Ni and Co in a content of 0.1 to 2 atomic percent, and
wherein the Al alloy film comprises at least one Ge-enriched area being present at an aluminum matrix grain boundary and having a Ge concentration (atomic percent) of more than 1.8 times the Ge concentration (atomic percent) of the entire Al alloy film.

12. The Al alloy film according to claim 11, wherein the Al alloy film has a ratio [Ge/(Ni+Co)] of the Ge content to the total content of Ni and Co of 1.2 or more.

13. The Al alloy film according to claim 11, further comprising, of the Element Group X, Cu in a content of 0.1 to 6 atomic percent.

14. The Al alloy film according to claim 13, wherein the Al alloy film has a ratio [Cu/(Ni+Co)] of the Cu content to the total content of Ni and Co of 0.5 or less.

15. A display device comprising at least one thin-film transistor comprising the Al alloy film according to claim 1.

16. A sputtering target for depositing an Al alloy film, the Al alloy film to be arranged on or above a substrate of a display device and to be directly connected to a transparent conductive film,
the sputtering target comprising:
Ge in a content of 0.05 to 2.0 atomic percent;
at least one element selected from the Element Group X consisting of Ag, Ni, Co, Zn, and Cu; and
at least one element selected from the Element Group Q consisting of rare-earth elements in a content of 0.02 to 2 atomic percent,
with the remainder including Al and inevitable impurities.

17. The sputtering target according to claim 16, comprising:
Ge in a content of 0.05 to 1.0 atomic percent;
at least one element selected from, of the Element Group X, the group consisting of Ni, Ag, Co, and Zn in a content of 0.03 to 2.0 atomic percent; and
at least one element selected from the Element Group Q consisting of rare-earth elements in a content of 0.05 to 0.5 atomic percent.

18. The sputtering target according to claim 17, further comprising, of the Element Group X, Cu in a content of 0.1 to 0.5 atomic percent.

19. The sputtering target according to claim 16, wherein the sputtering target has a ratio [(Group X element)/(Group Q element)] of more than 0.1 and 7 or less, wherein the ratio is the ratio of the content (atomic percent) of the at least one element selected from the Element Group X (Group X element) to the content (atomic percent) of the at least one element selected from the Element Group Q (Group Q element).

20. The display device of claim 15, wherein the alloy film is arranged on or above a substrate of the display device and is directly connected to a transparent conductive film.
